(19) United States
(12) Patent Application Publication
(10) Pub. No.: US 2026/0040806 A1
(43) Pub. Date: Feb. 5, 2026

(54) DISPLAY DEVICE AND METHOD OF MANUFACTURING THE SAME

(71) Applicant: Samsung Display Co., LTD., Yongin-si (KR)

(72) Inventors: Ki-Lim Han, Yongin-si (KR); EOK SU KIM, Yongin-si (KR); YUNYONG NAM, Yongin-si (KR); SOYOUNG KOO, Yongin-si (KR); HYUNGJUN KIM, Yongin-si (KR)

(73) Assignee: Samsung Display Co., LTD., Yongin-si (KR)

(21) Appl. No.: 18/396,975

(22) Filed: Dec. 27, 2023

(30) Foreign Application Priority Data
Mar. 30, 2023 (KR) 10-2023-0042214

(51) Int. Cl. H10K 71/70; H10K 59/131

(52) U.S. Cl. CPC H10K 71/70; H10K 59/131

(57) ABSTRACT

A display device includes a display area and a test area disposed adjacent to the display area and a first test element disposed on a substrate in the test area. The first test element includes a first pad part including a first-first voltage pad, a first-second voltage pad, a first current pad, and a first ground pad, a first test pattern electrically connecting the first-first voltage pad and the first ground pad, and a second test pattern contacting the first test pattern and electrically connecting the first current pad and the first-second voltage pad. In an area where the first test pattern and the second test pattern contact each other, a direction of a first current that flows into the first ground pad and a direction of a second current that flows into the first-first voltage pad are opposite to each other.

### CROSS REFERENCE TO RELATED APPLICATION(S)

This application claims priority to and benefits of Korean Patent Application No. 10-2023-0042214 under 35 USC § 119, filed on Mar. 30, 2023, in the Korean Intellectual Property Office (KIPO), the entire contents of which are incorporated herein by reference.

### BACKGROUND

### 1. Technical Field

Embodiments relate to a display device and a method of manufacturing the same.

### 2. Description of the Related Art

A display device displays an image through pixels that emit light with a luminance corresponding to a driving current. The display device may include an active pattern and an electrode contacting the active pattern to generate the driving current. The electrode may contact the active pattern through a contact hole, and contact resistance may be generated between the active pattern and the electrode.

To measure the contact resistance, multiple test element group (TEG) patterns having shapes and areas may be formed in a peripheral area of a display substrate. By applying a voltage (e.g., a predetermined or selectable voltage) or a current (e.g., a predetermined or selectable current) to the test element group (TEG) patterns and measuring the contact resistance of the test element group (TEG), the contact resistance between the active pattern and the electrode may be estimated.

### SUMMARY

The disclosure provides a display device capable of estimating contact resistance more accurately.

The disclosure provides a method of manufacturing the display device.

A display device according to an embodiment of the disclosure may include a display area and a test area disposed adjacent to the display area and a first test element disposed on a substrate in the test area. The first test element may include a first pad part including a first-first voltage pad, a first-second voltage pad, a first current pad, and a first ground pad, a first test pattern electrically connecting the first-first voltage pad and the first ground pad, and a second test pattern contacting the first test pattern and electrically connecting the first current pad and the first-second voltage pad. In an area where the first test pattern and the second test pattern contact each other, a direction of a first current that flows into the first ground pad and a direction of a second current that flows into the first-first voltage pad may be opposite to each other.

In an embodiment, the first current may flow into the first ground pad through the first current pad, the second test pattern, and the first test pattern. The second current may flow into the first-first voltage pad through the first-first voltage pad, the second test pattern, and the first test pattern.

In an embodiment, the first-first voltage pad, the first current pad, the first ground pad, and the first-second voltage pad may be arranged side by side in a first direction.

In an embodiment, the first current pad, the first-first voltage pad, the first-second voltage pad, and the first ground pad may be arranged side by side in a first direction.

In an embodiment, the display device may further include an active pattern disposed on the substrate in the display area and a gate electrode layer disposed on the active pattern. The first test pattern and the active pattern may be disposed on a same layer. The gate electrode layer and each of the second test pattern and the first pad part may be disposed on a same layer.

In an embodiment, the first test pattern and the active pattern may include a same material. The gate electrode layer and each of the second test pattern and the first pad part may include a same material.

In an embodiment, the display device may further include a second test element disposed on the substrate in the test area. The second test element may include a second pad part including a second-first voltage pad, a second-second voltage pad, a second current pad, and a second ground pad, a third test pattern electrically connecting the second-first voltage pad and the second ground pad, a fourth test pattern electrically connecting the second current pad and the second-second voltage pad, and a connection pattern electrically connecting the third test pattern and the fourth test pattern. In an area where the connection pattern and the fourth test pattern contact each other, a direction of a third current that flows into the second ground pad and a direction of a fourth current that flows into the second-first voltage pad may be the same.

In an embodiment, the third current may flow into the second ground pad through the second current pad, the fourth test pattern, the connection pattern, and the third test pattern. The fourth current may flow into the second-first voltage pad through the second-second voltage pad, the fourth test pattern, the connection pattern, and the third test pattern.

In an embodiment, the second current pad, the second-first voltage pad, the second ground pad, and the second-second voltage pad may be arranged side by side in a first direction.

In an embodiment, the display device may further include an active pattern disposed on the substrate in the display area and a gate electrode layer disposed on the active pattern. The active pattern and each of the third test pattern and the connection pattern may be disposed on a same layer. The gate electrode layer and each of the fourth test pattern and the second pad part may be disposed on a same layer.

In an embodiment, the active pattern and each of the third test pattern and the connection pattern may include a same material. The gate electrode layer and each of the fourth test pattern and the second pad part may include a same material.

A method of manufacturing a display device according to an embodiment of the disclosure may include providing a substrate including a display area and a test area disposed adjacent to the display area, forming a first pad part including a first-first voltage pad, a first-second voltage pad, a first current pad, and a first ground pad on the substrate in the test area, forming a first test pattern electrically connecting the first-first voltage pad and the first ground pad on the substrate in the test area, and forming a second test pattern contacting the first test pattern and electrically connecting the first current pad and the first-second voltage pad on the substrate in the test area. In an area where the first test pattern and the second test pattern contact each other, a direction of a first current that flows into the first ground pad and a direction of a second current that flows into the first-first voltage pad may be opposite to each other.

In an embodiment, the method may further include applying the first current from the first current pad to the first ground pad, applying the second current from the first-second voltage pad to the first-first voltage pad, measuring a first voltage between the first-first voltage pad and the first-second voltage pad, and calculating a first resistance of the area where the first test pattern and the second test pattern contact each other by using the first current and the first voltage.

In an embodiment, the first-first voltage pad, the first current pad, the first ground pad, and the first-second voltage pad may be formed side by side in a first direction.

In an embodiment, the first current pad, the first-first voltage pad, the first-second voltage pad, and the first ground pad may be formed side by side in a first direction.

In an embodiment, the method may further include forming an active pattern on the substrate in the display area and forming a gate electrode layer on the active pattern. The first test pattern and the active pattern may be formed simultaneously. The gate electrode layer, the second test pattern, and the first pad part may be formed simultaneously.

In an embodiment, the method may further include forming a second pad part including a second-first voltage pad, a second-second voltage pad, a second current pad, and a second ground pad on the substrate in the test area, forming a third test pattern electrically connecting the second-first voltage pad and the second ground pad on the substrate in the test area, forming a fourth test pattern electrically connecting the second current pad and the second-second voltage pad on the substrate in the test area, and forming a connection pattern electrically connecting the third test pattern and the fourth test pattern on the substrate in the test area. In an area where the connection pattern and the fourth test pattern contact each other, a direction of a third current that flows into the second ground pad and a direction of a fourth current that flows into the second-first voltage pad may be the same.

In an embodiment, the method may further include applying the third current from the second current pad to the second ground pad, applying the fourth current from the second-second voltage pad to the second-first voltage pad, measuring a second voltage between the second-first voltage pad and the second-second voltage pad, and calculating a second resistance by using the third current and the second voltage.

In an embodiment, the second resistance may include a resistance of the area where the connection pattern and the fourth test pattern contact each other. The second resistance may be greater than the first resistance.

In an embodiment, the first resistance and a resistance value of a resistance of the area where the connection pattern and the fourth test pattern contact each other may be equal.

A display device according to an embodiment of the disclosure may include a substrate including a display area and a test area adjacent to the display area, and a first test element disposed on the substrate in the test area. The first test element may include a first test pattern and a second test pattern contacting the first test pattern. In a contact area where the first test pattern and the second test pattern contact each other, a direction of a first current that flows into a first ground pad may be opposite to a direction of a second current that flows into a first-first voltage pad.

In case that the direction of the first current and the direction of the second current are opposite to each other at the contact area, a path of the first current and a path of the second current may overlap only at the contact area in a plan view. Accordingly, the first test element may measure a contact resistance between the first test pattern and the second test pattern, and a parasitic resistance other than the contact resistance may not be measured.

Accordingly, the first test element may more accurately estimate a contact resistance between an active pattern and a gate electrode layer that are disposed in the display area.

### BRIEF DESCRIPTION OF THE DRAWINGS

Illustrative, non-limiting embodiments will be more clearly understood from the following detailed description in conjunction with the accompanying drawings.

FIG. 1 is a schematic plan view illustrating a display device according to an embodiment of the disclosure.

FIG. 2 is a schematic cross-sectional view taken along line I-I′ of FIG. 1.

FIG. 3 is a schematic plan view illustrating a test element included in the display device of FIG. 1 according to an embodiment of the disclosure.

FIG. 4 is a schematic enlarged plan view of area ‘A’ of FIG. 3.

FIG. 5 is a schematic cross-sectional view taken along line II-II′ of FIG. 4.

FIG. 6 is a schematic cross-sectional view taken along line III-III′ of FIG. 4.

FIG. 7 is a schematic enlarged plan view of area ‘A’ of FIG. 3.

FIG. 8 is a schematic diagram of an equivalent circuit illustrating resistances of FIG. 7.

FIG. 9 is a schematic plan view illustrating a test element included in the display device of FIG. 1 according to another embodiment of the disclosure.

FIG. 10 is a schematic plan view illustrating a display device according to another embodiment of the disclosure.

FIG. 11 is a schematic plan view illustrating a second test element included in the display device of FIG. 10.

FIG. 12 is a schematic enlarged plan view of area ‘B’ of FIG. 11.

FIG. 13 is a schematic cross-sectional view taken along line IV-IV′ of FIG. 12.

FIG. 14 is a schematic enlarged plan view of area ‘B’ of FIG. 11.

FIG. 15 is a schematic diagram of an equivalent circuit illustrating resistances of FIG. 14.

FIG. 16 is a schematic flowchart of a method of manufacturing a display device according to an embodiment of the disclosure.

FIGS. 17, 18, 19, 20, 21, 22, 23, 24, 25, 26, and 27 are schematic diagrams illustrating a method of manufacturing the display device of FIG. 16.

### DETAILED DESCRIPTION OF THE EMBODIMENTS

In the following description, for the purposes of explanation, numerous specific details are set forth in order to provide a thorough understanding of various embodiments or implementations of the disclosure. As used herein “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in another embodiment.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” “including,” “has,” and/or “having” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

When an element, such as a layer, film, region, or substrate is referred to as being “on” or “connected to” another element, it may be directly on, connected to, or coupled to the other element or intervening elements may be present. When, however, an element or layer is referred to as being “directly on” or “directly connected to” another element or layer, there are no intervening elements or layers present. To this end, the term “connected” may refer to physical, electrical, and/or fluid connection, with or without intervening elements. Further, the first direction DR1, the second direction DR2, and the third direction are not limited to three axes of a rectangular coordinate system, such as the x, y, and z axes, and may be interpreted in a broader sense. For example, the first direction DR1, the second direction DR2, and the third direction may be perpendicular to one another, or may represent different directions that are not perpendicular to one another. For the purposes of this disclosure, “at least one of X, Y, and Z” and “at least one selected from the group consisting of X, Y, and Z” may be construed as X only, Y only, Z only, or any combination of two or more of X, Y, and Z, such as, for instance, XYZ, XYY, YZ, and ZZ. As used herein, the term “and/or” includes any and all combinations of one or more of the associated listed items.

It will be understood that when an element such as a layer, film, region, or substrate is referred to as being “on,” “over,” or “above” another element, it can be directly on the other element or intervening element(s) may also be present. In contrast, when an element is referred to as being “directly on”another element, no intervening elements are present.

Spatially relative terms, such as “lower,” “upper,” “side,” and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the example term “below” can encompass both an orientation of above and below. Furthermore, the apparatus may be otherwise oriented (e.g., rotated 90 degrees or at other orientations), and, as such, the spatially relative descriptors used herein interpreted accordingly.

In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

When a component is described herein to “connect” another component to the other component or to be “connected to” other components, the components may be connected to each other as separate elements, or the components may be integral with each other.

Throughout the specification, when an element is referred to as being “connected” to another element, the element may be “directly connected” to another element, or “electrically connected” to another element with one or more intervening elements interposed therebetween. Also, when an element is referred to as being “in contact” or “contacted” or the like to another element, the element may be in “electrical contact” or in “physical contact” with another element; or in “indirect contact” or in “direct contact” with another element.

Unless otherwise specified, the illustrated embodiments are to be understood as providing example features of the disclosure. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the disclosure.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

The display surface may be parallel to a surface defined by a first direction DR1 and a second direction DR2. A normal direction of the display surface, i.e., a thickness direction of the display device DD, may indicate a third direction. In this specification, an expression of “when viewed from the top or in a plan view” may represent a case when viewed in the third direction. Hereinafter, a front surface (or a top surface) and a rear surface (or a bottom surface) of each of layers or units may be distinguished by the third direction. However, directions indicated by the first direction DR1, the second direction DR2, and the third direction may be a relative concept, and converted with respect to each other, e.g., converted into opposite directions.

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification.

Hereinafter, embodiments of the disclosure will be described in detail with reference to the accompanying drawings. The same reference numerals are used for the same components in the drawings, and redundant descriptions of the same components will be omitted.

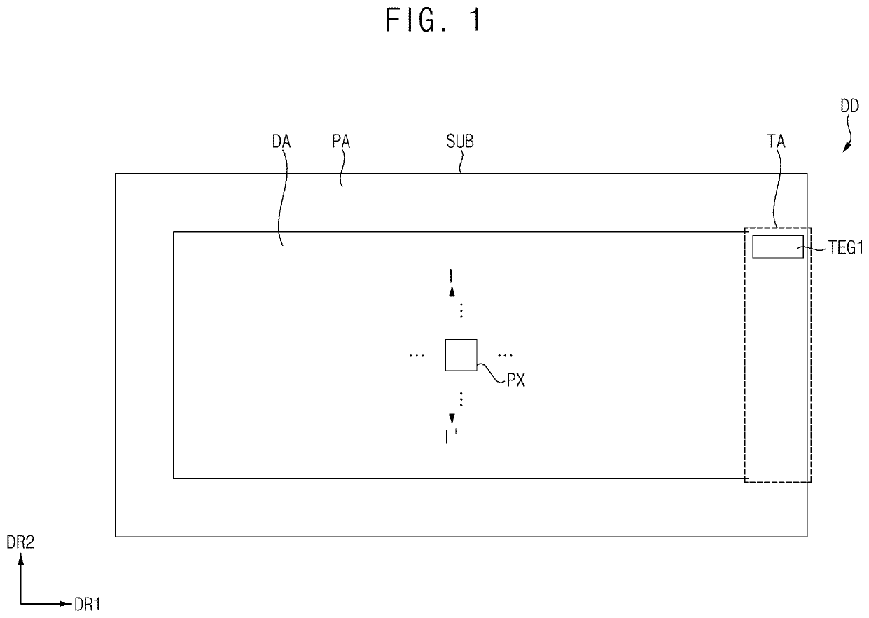

FIG. 1 is a schematic plan view illustrating a display device according to an embodiment of the disclosure.

In this specification, a plane may be defined by a first direction DR1 and a second direction DR2 intersecting the first direction DR1. For example, the first direction DR1 and the second direction DR2 may be perpendicular to each other. The display device DD and various components or layers of the display device DD may have a thickness extended in a third direction which intersects the plane, for example, each of the first direction DR1 and the second direction DR2.

Referring to FIG. 1, the display device DD according to an embodiment of the disclosure may include a substrate SUB and a test element TEG1.

The substrate SUB may include a display area DA and a peripheral area PA. The display area DA may be defined as an area capable of displaying an image by generating light or adjusting transmittance of light provided from an external light source.

Multiple pixels PX may be disposed on the substrate SUB in the display area DA. Each of the pixels PX may emit light. The pixels PX may be repeatedly arranged in the first direction DR1 and the second direction DR2.

The peripheral area PA may be defined as an area not displaying an image. The peripheral area PA may be disposed adjacent to the display area DA. In an embodiment, the peripheral area PA may surround at least a portion of the display area DA.

In an embodiment, a test area TA may be disposed inside the peripheral area PA. The test area TA may be disposed adjacent to the display area DA. The test area TA may surround at least a portion of the display area DA.

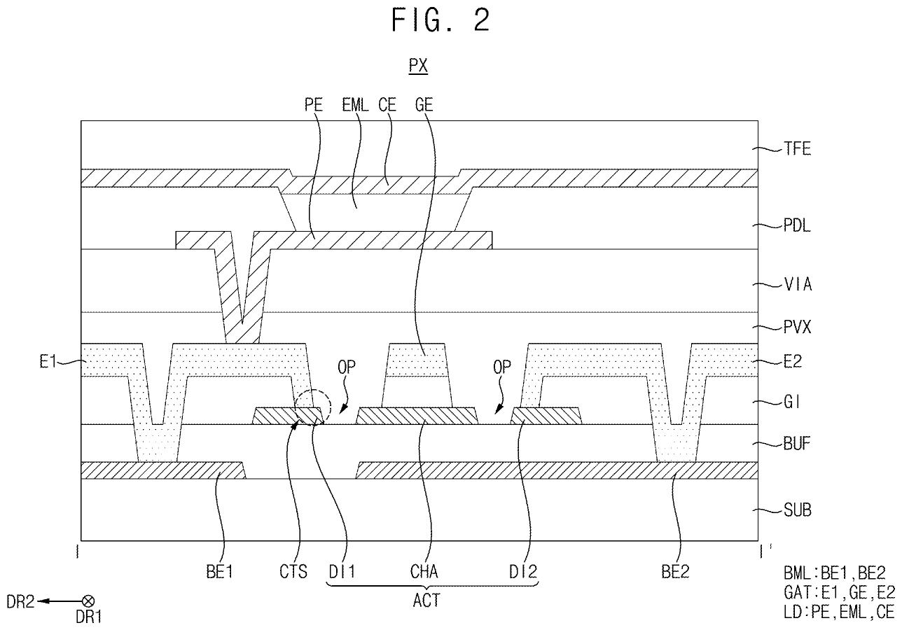

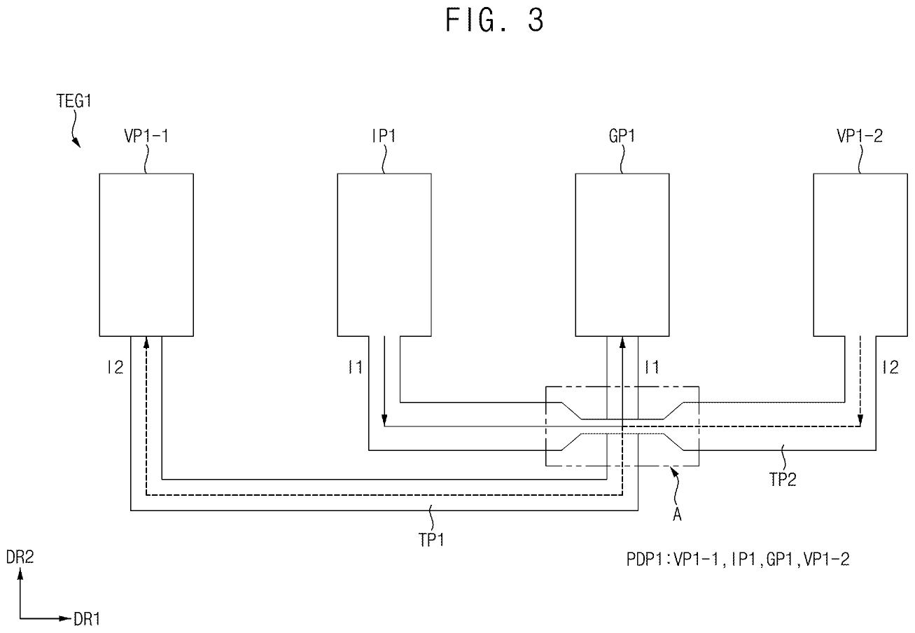

A test element TEG1 may be disposed on the substrate SUB in the test area TA. The test element TEG1 may include multiple pads (see, e.g., a first-first voltage pad VP1-1, a first current pad IP1, a first ground pad GP1, and a first-second voltage pad VP1-2 of FIG. 3) and multiple test patterns (see, e.g., a first test pattern TP1 and a second test pattern TP2 of FIG. 3). The test element TEG1 may measure a contact resistance between a gate electrode layer (see, e.g., GAT of FIG. 2) and an active pattern (see, e.g., ACT of FIG. 2) included in each of the pixels PX. A detailed description thereof will be described below with reference to FIGS. 3, 4, 5, 6, 7, and 8.

FIG. 2 is a schematic cross-sectional view taken along line I-I′ of FIG. 1.

Referring to FIG. 2, each of the pixels PX may include a substrate SUB, a lower electrode layer BML, a buffer layer BUF, an active pattern ACT, a gate insulating layer GI, a gate electrode layer GAT, a passivation layer PVX, a via-insulating layer VIA, a light emitting element LD, a pixel defining layer PDL, and an encapsulation layer TFE. The light emitting element LD may include a pixel electrode PE, a light emitting layer EML, and a common electrode CE.

The substrate SUB may include a transparent material or an opaque material. The substrate SUB may be a transparent resin substrate such as polyimide substrate or the like. The substrate SUB may include a first organic layer, a first barrier layer, a second organic layer, the like, or a combination thereof. In another embodiment, the substrate SUB may be a quartz substrate, a synthetic quartz substrate, a calcium fluoride substrate, a fluorine-doped quartz substrate, a soda-lime glass substrate, a non-alkali glass substrate, the like, or a combination thereof.

The lower electrode layer BML may be disposed on the substrate SUB. The lower electrode layer BML may include a metal, an alloy, a metal nitride, a conductive metal oxide, a transparent conductive material, the like, or a combination thereof. For example, the lower electrode layer BML may include silver (Ag), an alloy including silver, molybdenum (Mo), an alloy including molybdenum, aluminum (Al), an alloy including aluminum, aluminum nitride (AIN), tungsten (W), tungsten nitride (WN), copper (Cu), nickel (Ni), chromium (Cr), chromium nitride (CrN), titanium (Ti), tantalum (Ta), platinum (Pt), scandium (Sc), indium tin oxide (ITO), indium zinc oxide (IZO), the like, or a combination thereof.

The lower electrode layer BML may include a first lower electrode BE1 and a second lower electrode BE2. The first lower electrode BE1 and the second lower electrode BE2 may be spaced apart from each other. In an embodiment, different types of electrical signals may be applied to the first lower electrode BE1 and the second lower electrode BE2.

The buffer layer BUF may be disposed on the substrate SUB and the lower electrode layer BML. The buffer layer BUF may prevent diffusion of metal atoms or impurities from the substrate SUB to upper structures (e.g., the active pattern ACT, the gate electrode layer GAT, and the like). The buffer layer BUF may improve flatness of a surface of the substrate SUB in case that the surface of the substrate SUB is not uniform. For example, the buffer layer BUF may include an inorganic material such as silicon oxide (SiOₓ), silicon nitride (SiNₓ), silicon oxynitride (SiOₓN_{y}), the like, or a combination thereof.

The active pattern ACT may be disposed on the buffer layer BUF. The active pattern ACT may include an oxide semiconductor, a silicon semiconductor, an organic semiconductor, or the like. For example, the active pattern ACT may include an oxide semiconductor including indium (In), gallium (Ga), tin (Sn), zirconium (Zr), vanadium (V), hafnium (Hf), cadmium (Cd), germanium (Ge), chromium (Cr), titanium (Ti), zinc (Zn), the like, or a combination thereof. The active pattern ACT may include a silicon semiconductor including amorphous silicon, polycrystalline silicon, the like, or a combination thereof. The active pattern ACT may include a first conductor area DI1, a second conductor area DI2, and a channel area CHA disposed between the first conductor area DI1 and the second conductor area DI2. For example, the first conductor area DI1 and the second conductor area DI2 may be spaced apart from each other with the channel area CHA interposed between the first conductor area DI1 and the second conductor area DI2.

For example, each of the first conductor area DI1 and the second conductor area DI2 may be a doped area doped with impurities, and the channel area CHA may be a non-doped area or an area doped with a lower concentration compared to the first conductor area DI1 and the second conductor area DI2.

In an embodiment, in a process of etching the gate electrode layer GAT and the gate insulating layer GI during a manufacturing process of the display device DD, a portion of the active pattern ACT not covered by the gate insulating layer GI may be removed. Accordingly, an opening OP penetrating the active pattern ACT in a thickness direction of the display device DD may be defined in a partial area of the active pattern ACT. However, by bypassing the opening OP, the channel area CHA and the first conductor area DI1 may be electrically connected, and the channel area CHA and the second conductor area DI2 may be electrically connected.

The gate insulating layer GI may be disposed on the buffer layer BUF and the active pattern ACT. The gate insulating layer GI may expose a portion of the active pattern ACT. For example, the gate insulating layer GI may include an inorganic material such as silicon oxide (SiOₓ), silicon nitride (SiNₓ), silicon oxynitride (SiOₓN_{y}), the like, or a combination thereof.

The gate electrode layer GAT may be disposed on the lower electrode layer BML, the active pattern ACT, and the gate insulating layer GI. The gate electrode layer GAT may include a metal, an alloy, a metal nitride, a conductive metal oxide, a transparent conductive material, the like, or a combination thereof.

The gate electrode layer GAT may include a first electrode E1, a second electrode E2, and a gate electrode GE. The first electrode E1, the second electrode E2, and the gate electrode GE may be spaced apart from each other.

The first electrode E1 may be electrically connected to the first lower electrode BE1. The first electrode E1 may be electrically connected to the first lower electrode BE1 through a contact hole penetrating the buffer layer BUF and the gate insulating layer GI. The first electrode E1 may be electrically connected to the first conductor area DI1. The first electrode E1 may be electrically connected to the first conductor area DI1 not covered by the gate insulating layer GI.

The gate electrode GE may overlap the channel area CHA of the active pattern ACT in a plan view.

The second electrode E2 may be electrically connected to the second lower electrode BE2. The second electrode E2 may be electrically connected to the second lower electrode BE2 through a contact hole penetrating the buffer layer BUF and the gate insulating layer GI. The second electrode E2 may be electrically connected to the second conductor area DI2. The second electrode E2 may be electrically connected to the second conductor area DI2 not covered by the gate insulating layer GI.

A contact structure between the second electrode E2 and the second conductor area DI2 and a contact structure CTS between the first electrode E1 and the first conductor area DI1 may have substantially a same or symmetric structures. Therefore, hereinafter, the contact structure CTS between the first electrode E1 and the first conductor area DI1 will be described. A description of the contact structure CTS between the first electrode E1 and the first conductor area DI1 and a description of the contact structure between the second electrode E2 and the second conductor area DI2 may be same.

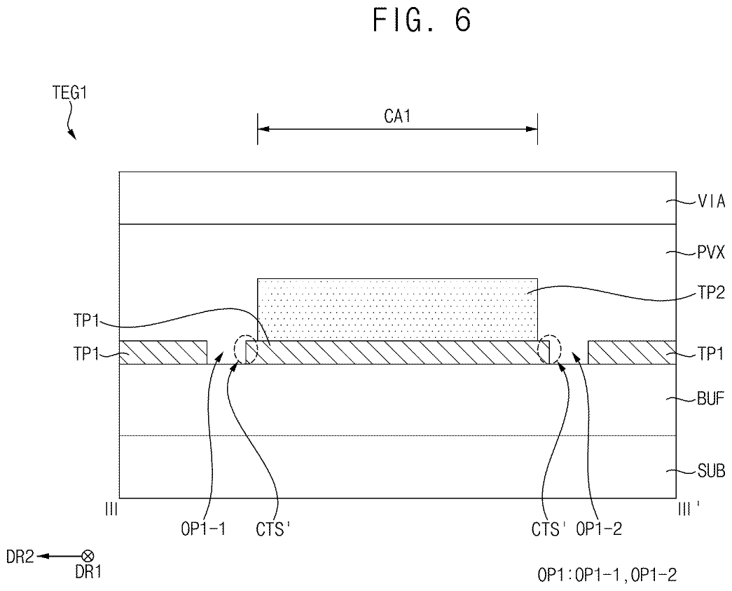

To measure a contact resistance between the first electrode E1 and the first conductor area DI1, the test element (see, e.g., TEG1 of FIG. 1) and the contact structure CTS between the first electrode E1 and the first conductor area DI1 may include a substantially identical structure (see, e.g., a contact structure CTS′ of FIG. 6). A detailed description thereof will be described below with reference to FIG. 6.

In an embodiment, the first electrode E1, the second electrode E2, the gate electrode GE, and the active pattern ACT may constitute a transistor. For example, the gate electrode GE may serve as a gate electrode of the transistor, and the first and second electrodes E1 and E2 may serve as source and drain electrodes of the transistor.

The passivation layer PVX may be disposed on the buffer layer BUF and the gate electrode layer GAT. The passivation layer PVX may cover the first electrode E1, the second electrode E2, and the gate electrode GE. The passivation layer PVX may cover the active pattern ACT not covered by the gate insulating layer GI. For example, the passivation layer PVX may include an inorganic material such as silicon oxide (SiOₓ), silicon nitride (SiNₓ), silicon oxynitride (SiOₓN_{y}), the like, or a combination thereof. The passivation layer PVX may have a single-layer structure or a multi-layer structure.

The via-insulating layer VIA may be disposed on the passivation layer PVX. The via-insulating layer VIA may include an organic material. The via-insulating layer VIA may include an organic material such as photoresist, a polyacryl-based resin, a polyimide-based resin, a polyamide-based resin, a siloxane-based resin, an epoxy-based resin, the like, or a combination thereof.

The pixel electrode PE may be disposed on the via-insulating layer VIA. The pixel electrode PE may be electrically connected to the first electrode E1 through a contact hole penetrating the via-insulating layer VIA and the passivation layer PVX. Accordingly, the pixel electrode PE may be electrically connected to the transistor. The pixel electrode PE may include a metal, an alloy, a metal nitride, a conductive metal oxide, a transparent conductive material, the like, or a combination thereof. For example, the pixel electrode PE may serve as an anode electrode.

The pixel defining layer PDL may be disposed on the via-insulating layer VIA. The pixel-defining layer PDL may cover an edge of the pixel electrode PE and may expose a portion of an upper surface of the pixel electrode PE. The pixel defining layer PDL may include an organic material and/or an inorganic material. The pixel defining layer PDL may include an organic material such as photoresist, a polyacryl-based resin, a polyimide-based resin, a polyamide-based resin, a siloxane-based resin, an epoxy-based resin, the like, or a combination thereof.

The light emitting layer EML may be disposed on the pixel electrode PE. The light emitting layer EML may be disposed on the upper surface of the pixel electrode PE, at least partially of which is exposed. The light emitting layer EML may include an organic material that emits light of a color. For example, the light emitting layer EML may include an organic material that emits at least one of red light, green light, and blue light. The light emitting layer EML may have a multi-layer structure including a hole injection layer, a hole transport layer, an organic light emitting layer, an electron transport layer, an electron injection layer, and the like.

The common electrode CE may be disposed on the pixel defining layer PDL and the light emitting layer EML. The common electrode CE may cover the pixel defining layer PDL and the light emitting layer EML, and may be disposed along profiles of the pixel defining layer PDL and the light emitting layer EML with a uniform thickness. The common electrode CE may include a metal, an alloy, a metal nitride, a conductive metal oxide, a transparent conductive material, the like, or a combination thereof. For example, the common electrode CE may serve as a cathode electrode.

Accordingly, the light emitting element LD including the pixel electrode PE, the light emitting layer EML, and the common electrode CE may be formed.

The encapsulation layer TFE may be disposed on the common electrode CE. The encapsulation layer TFE may prevent impurities, moisture, and the like from permeating the light emitting element LD from an outside. The encapsulation layer TFE may include at least one inorganic encapsulation layer and at least one organic encapsulation layer. For example, the inorganic encapsulation layer may include silicon oxide (SiOₓ), silicon nitride (SiNₓ), silicon oxynitride (SiOₓN_{y}), the like, or a combination thereof. For example, the organic encapsulation layer may include a polymer cured material such as polyacrylate or the like.

Although the display device DD of the disclosure is described as an organic light emitting display device (OLED), the disclosure is not limited thereto. In another embodiment, the display device DD may be a liquid crystal display device (LCD), a field emission display device (FED), a plasma display device (PDP), an electrophoretic image display device (EPD), an inorganic light emitting display device (ILED), or a quantum dot display device.

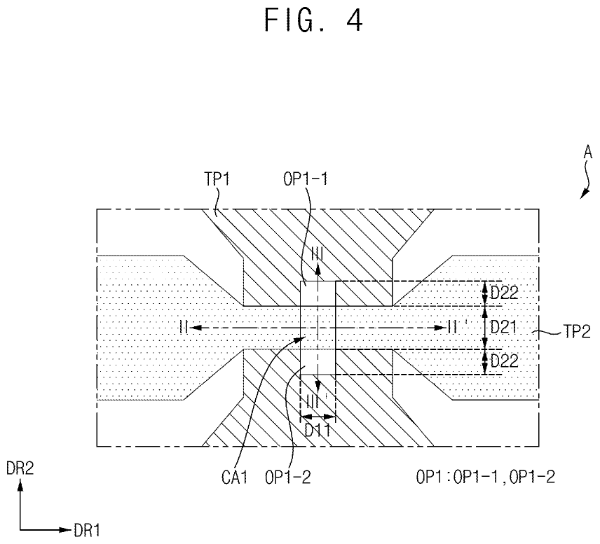

FIG. 3 is a schematic plan view illustrating a test element included in the display device of FIG. 1 according to an embodiment of the disclosure. FIG. 4 is a schematic enlarged plan view of area ‘A’ of FIG. 3.

Referring to FIGS. 1, 3, and 4, the display device DD according to an embodiment of the disclosure may include the test element TEG1 disposed on the substrate SUB in the test area TA. The test element TEG1 may include a first pad part PDP1, a first test pattern TP1, and a second test pattern TP2.

The first pad part PDP1 may be disposed on the substrate SUB in the test area TA. The first pad part PDP1 may include a first-first voltage pad VP1-1, a first-second voltage pad VP1-2, a first current pad IP1, and a first ground pad GP1.

In an embodiment, the first pad part PDP1 may be arranged in the order of the first-first voltage pad VP1-1, the first current pad IP1, the first ground pad GP1, and the first-second voltage pad VP1-2 in the first direction DR1. For example, the first-first voltage pad VP1-1, the first current pad IP1, the first ground pad GP1, and the first-second voltage pad VP1-2 may be disposed side by side in the first direction DR1. However, the disclosure is not limited thereto.

In an embodiment, the first pad part PDP1 of FIG. 3 and the gate electrode layer (see, e.g., GAT of FIG. 2) may be disposed on a same layer. The first pad part PDP1, the first electrode (see, e.g., E1 of FIG. 2), the second electrode (see, e.g., E2 of FIG. 2), and the gate electrode (see, e.g., GE of FIG. 2) may be disposed on a same layer. For example, the first pad part PDP1, the first electrode, the second electrode, and the gate electrode may include a same material, and may be formed by a same process.

The first test pattern TP1 may be disposed on the substrate SUB in the test area TA. The first test pattern TP1 may electrically connect the first-first voltage pad VP1-1 and the first ground pad GP1. The first test pattern TP1 may be electrically connected to each of the first-first voltage pad VP1-1 and the first ground pad GP1 in the second direction DR2 and may extend in the first direction DR1.

In an embodiment, the first test pattern TP1 and the active pattern (see, e.g., ACT of FIG. 2) may be disposed on a same layer. For example, the first test pattern TP1 and the active pattern may include a same material, and may be formed by a same process.

The second test pattern TP2 may be disposed on the substrate SUB in the test area TA. The second test pattern TP2 may electrically connect the first current pad IP1 and the first-second voltage pad VP1-2. The second test pattern TP2 may be electrically connected to each of the first current pad IP1 and the first-second voltage pad VP1-2 in the second direction DR2 and may extend in the first direction DR1. The second test pattern TP2 may contact the first test pattern TP1 at a contact area CA1.

In an embodiment, the second test pattern TP2 may be disposed on the first test pattern TP1.

In an embodiment, the second test pattern TP2 and the gate electrode layer may be disposed on a same layer. The second test pattern TP2, the first electrode, the second electrode, and the gate electrode may be disposed on a same layer. For example, the second test pattern TP2, the first electrode, the second electrode, and the gate electrode may include a same material, and may be formed by a same process.

In an embodiment, the second test pattern TP2 and the first pad part PDP1 may be disposed on a same layer.

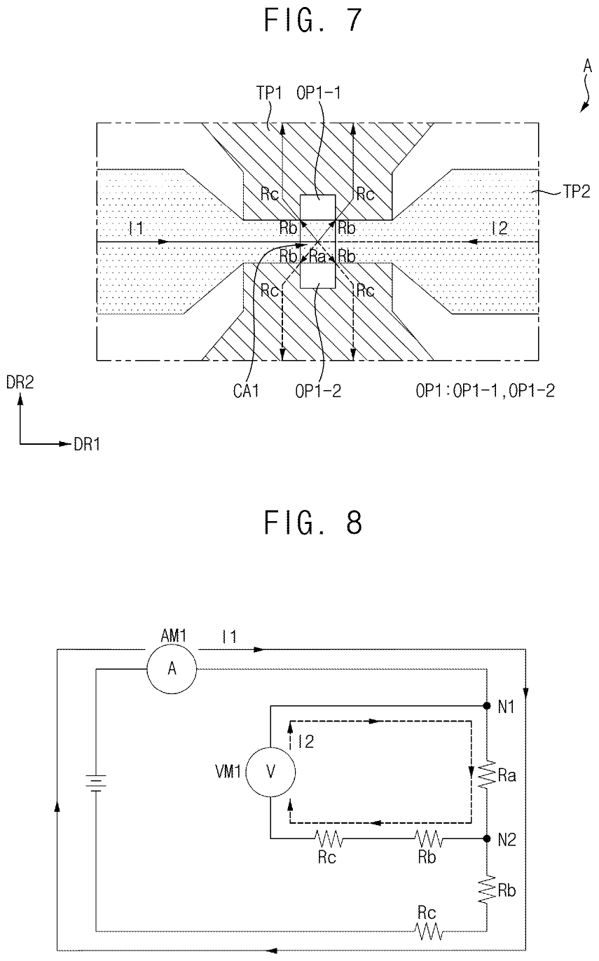

To measure the contact resistance (see, e.g., resistance A Ra of FIG. 7) between the first test pattern TP1 and the second test pattern TP2 at the contact area CA1, each of a first current I1 and a second current I2 may be applied.

The first current I1 may be applied from the first current pad IP1 to the first ground pad GP1. The first current I1 may flow into the first ground pad GP1 through the first current pad IP1, the second test pattern TP2, and the first test pattern TP1.

The second current I2 may be applied from the first-second voltage pad VP1-2 to the first-first voltage pad VP1-1. The second current I2 may flow into the first-first voltage pad VP1-1 through the first-second voltage pad VP1-2, the second test pattern TP2, and the first test pattern TP1. A method of measuring the contact resistance by applying each of the first current I1 and the second current I2 will be described below with reference to FIGS. 7 and 8.

As illustrated in FIG. 4, the second test pattern TP2 may be disposed on the first test pattern TP1. For example, the second test pattern TP2 and the gate electrode layer may be disposed on a same layer, and the first test pattern TP1 and the active pattern may be disposed on a same layer. The second test pattern TP2 may contact the first test pattern TP1 at the contact area CA1.

First openings OP1 penetrating the first test pattern TP1 in the thickness direction may be defined in a partial area of the first test pattern TP1. The first openings OP1 may be spaced apart from each other in the second direction DR2 with the contact area CA1 interposed between the first openings OP1. Each of the first openings OP1 may correspond to the opening (see, e.g., OP of FIG. 2).

The first openings OP1 may include a (1-1)-th opening OP1-1 and a (1-2)-th opening OP1-2. The (1-1)-th opening OP1-1 may be disposed adjacent to the contact area CA1 in the second direction DR2. The (1-2)-th opening OP1-2 may be disposed adjacent to the contact area CA1 in a direction opposite to the second direction DR2.

For example, a length D11 of the contact area CA1 in the first direction DR1 may be about 4 micrometers. A length D21 of the contact area CA1 in the second direction DR2 may be about 4 micrometers. For example, the contact area CA1 may have a square shape in a plan view. However, the disclosure is not limited thereto. The length D11 of the contact area CA1 in the first direction DR1 and the length D21 of the contact area CA1 in the second direction DR2 may vary.

For example, the length D11 of each of the first openings OP1 in the first direction DR1 may be about 4 micrometers. A length D22 of each of the first openings OP1 in the second direction DR2 may be about 3 micrometers. For example, each of the first openings OP1 may have a rectangular shape in a plan view. However, the disclosure is not limited thereto. The length D11 of each of the first openings OP1 in the first direction DR1 and the length D22 of each of the first openings OP1 in the second direction DR2 may vary.

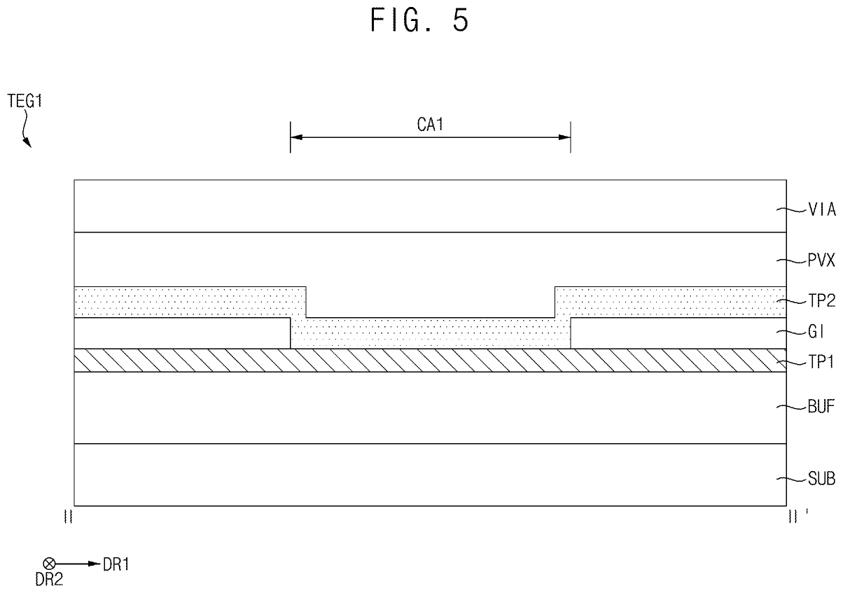

FIG. 5 is a schematic cross-sectional view taken along line II-II′ of FIG. 4. For example, FIG. 5 is a schematic cross-sectional view of the contact area CA1 taken along the first direction DR1. Hereinafter, duplicated descriptions of the display device DD of FIG. 2 will be omitted or simplified.

Referring to FIGS. 2 and 5, the test element TEG1 may include the substrate SUB, the buffer layer BUF, the first test pattern TP1, the gate insulating layer GI, the second test pattern TP2, the passivation layer PVX, and the via-insulating layer VIA.

The buffer layer BUF may be disposed on the substrate SUB, and the first test pattern TP1 may be disposed on the buffer layer BUF. The first test pattern TP1 and the active pattern ACT may include a same material, and may be formed by a same process.

The gate insulating layer GI may be disposed on the first test pattern TP1. An opening exposing a portion of the first test pattern TP1 at the contact area CA1 may be defined in the gate insulating layer GI.

The second test pattern TP2 may be disposed on the first test pattern TP1 and the gate insulating layer GI. The second test pattern TP2 may cover each of the gate insulating layer GI and the first test pattern TP1 and may be disposed along profiles of the gate insulating layer GI and the first test pattern TP1 with a uniform thickness. The second test pattern TP2 may contact the first test pattern TP1 at the contact area CA1. The second test pattern TP2 and the gate electrode layer GAT may include a same material, and may be formed by a same process.

The passivation layer PVX may be disposed on the second test pattern TP2, and the via-insulating layer VIA may be disposed on the passivation layer PVX. The passivation layer PVX may cover (e.g., sufficiently cover) the second test pattern TP2 and may have a substantially flat upper surface without creating a step difference on the second test pattern TP2.

FIG. 6 is a schematic cross-sectional view taken along line III-III′ of FIG. 4. For example, FIG. 6 is a schematic cross-sectional view of the first openings OP1 and the contact area CA1 taken along the second direction DR2. Hereinafter, duplicated descriptions of the display device DD of FIG. 2 will be omitted or simplified.

Referring to FIGS. 2 and 6, the test element TEG1 may include the substrate SUB, the buffer layer BUF, the first test pattern TP1, the second test pattern TP2, the passivation layer PVX, and the via-insulating layer VIA.

The buffer layer BUF may be disposed on the substrate SUB, and the first test pattern TP1 may be disposed on the buffer layer BUF. The first openings OP1 penetrating the first test pattern TP1 in the thickness direction may be defined in a partial area of the first test pattern TP1. The first openings OP1 may be spaced apart from each other in the second direction DR2 with the contact area CA1 interposed between the first openings OP1. Each of the first openings OP1 may correspond to the opening (see, e.g., OP of FIG. 2). The (1-1)-th opening OP1-1 may be disposed adjacent to the contact area CA1 in the second direction DR2. The (1-2)-th opening OP1-2 may be disposed adjacent to the contact area CA1 in the direction opposite to the second direction DR2. The first test pattern TP1 and the active pattern ACT may include a same material, and may be formed by a same process.

The second test pattern TP2 may be disposed on the first test pattern TP1 at the contact area CA1. For example, the second test pattern TP2 may contact the first test pattern TP1 at the contact area CA1. The second test pattern TP2 and the gate electrode layer GAT may include a same material, and may be formed by a same process.

In an embodiment, the test element TEG1 of FIG. 6 and the contact structure (see, e.g., CTS of FIG. 2) between the first electrode (see, e.g., E1 of FIG. 2) and the first conductor area (see, e.g., DI1 of FIG. 2) may include a substantially identical structure. For example, a contact structure CTS′ between the second test pattern TP2 and the first test pattern TP1 of FIG. 6 and the contact structure (see, e.g., CTS of FIG. 2) between the first electrode (see, e.g., E1 of FIG. 2) and the first conductor area (see, e.g., DI1 of FIG. 2) may be substantially the same.

Accordingly, by measuring a contact resistance between the first test pattern TP1 and the second test pattern TP2, the contact resistance between the first electrode (see, e.g., E1 of FIG. 2) of the gate electrode layer (see, e.g., GAT of FIG. 2) and the first conductor area (see, e.g., DI1 of FIG. 2) of the active pattern (see, e.g., ACT of FIG. 2) may be estimated.

The passivation layer PVX may be disposed on the buffer layer BUF, the first test pattern TP1, and the second test pattern TP2. The via-insulating layer VIA may be disposed on the passivation layer PVX. The passivation layer PVX may sufficiently cover the first test pattern TP1 and the second test pattern TP2 and may have a substantially flat upper surface without creating a step difference on the first test pattern TP1 and the second test pattern TP2.

FIG. 7 is a schematic enlarged plan view of area ‘A’ of FIG. 3. For example, FIG. 7 is a schematic plan view illustrating traveling directions of the first current I1 and the second current I2. FIG. 8 is a schematic diagram of an equivalent circuit illustrating resistances of FIG. 7.

Referring to FIGS. 3, 7, and 8, the test element TEG1 may include the first pad part PDP1, the first test pattern TP1, and the second test pattern TP2. The first pad part PDP1 may include the first-first voltage pad VP1-1, the first-second voltage pad VP1-2, the first current pad IP1, and the first ground pad GP1.

In an embodiment, the first-first voltage pad VP1-1, the first current pad IP1, the first ground pad GP1, and the first-second voltage pad VP1-2 may be disposed side by side in the first direction DR1.

The first test pattern TP1 may electrically connect the first-first voltage pad VP1-1 and the first ground pad GP1. The second test pattern TP2 may electrically connect the first current pad IP1 and the first-second voltage pad VP1-2.

The first current I1 may flow into the first ground pad GP1 through the first current pad IP1, the second test pattern TP2, and the first test pattern TP1. The first current I1 may flow from the second test pattern TP2 to the first test pattern TP1 at the contact area CA1. Since the (1-1)-th opening OP1-1 disposed adjacent to the contact area CA1 in the second direction DR2 is filled with the passivation layer (see, e.g., PVX of FIG. 6) including an insulating material, the first current I1 may not flow into the (1-1)-th opening OP1-1. For example, the first current I1 may flow in the first test pattern TP1 bypassing the (1-1)-th opening OP1-1.

The second current I2 may flow into the first-first voltage pad VP1-1 through the first-second voltage pad VP1-2, the second test pattern TP2, and the first test pattern TP1. The second current I2 may flow from the second test pattern TP2 to the first test pattern TP1 at the contact area CA1. Since the (1-2)-th opening OP1-2 disposed adjacent to the contact area CA1 in the direction opposite to the second direction DR2 is filled with the passivation layer (see, e.g., PVX of FIG. 6) including an insulating material, the second current I2 may not flow into the (1-2)-th opening OP1-2. For example, the second current I2 may flow in the first test pattern TP1 bypassing the (1-2)-th opening OP1-2.

Multiple resistances may be generated while each of the first current I1 and the second current I2 flows from the second test pattern TP2 to the first test pattern TP1. The resistances may include resistance A Ra, resistance B Rb, and resistance C Rc.

For example, the resistance A Ra may be a contact resistance between the first test pattern TP1 and the second test pattern TP2 at the contact area CA1. The resistance A Ra may be referred to as a first resistance. The resistance B Rb may be a resistance caused by flow of the first current I1 and the second current I2 bypassing the (1-1)-th opening OP1-1 or the (1-2)-th opening OP1-2 within the first test pattern TP1. The resistance C Rc may be an internal resistance of the first test pattern TP1.

In an embodiment, a direction of the first current I1 flowing from the contact area CA1 to the first ground pad GP1 may be opposite to a direction of the second current I2 flowing from the contact area CA1 to the first-first voltage pad VP1-1. For example, a path of the first current I1 and a path of the second current I2 may overlap at the contact area CA1 in a plan view and may not overlap in areas other than the contact area CA1 in a plan view.

For example, as illustrated in FIG. 8, the path of the first current I1 and the path of the second current I2 may overlap at the resistance A Ra and may not overlap at the resistance B Rb and the resistance C Rc.

Kelvin resistance measurement may be used to measure resistance. In case of using the Kelvin resistance measurement, a resistance value between a first node N1 and a second node N2 may be measured. For example, a resistance value of an area where the first current I1 and the second current I2 overlap in a plan view may be measured regardless of line resistance. For example, a resistance value of the resistance A Ra may be measured regardless of the resistance B Rb and the resistance C Rc.

In the test element TEG1, a parasitic resistance (e.g., the resistance B Rb and the resistance C Rc) other than the contact resistance (e.g., the resistance A Ra) between the first test pattern TP1 and the second test pattern TP2 may not be measured. Accordingly, the test element TEG1 may measure only the contact resistance between the first test pattern TP1 and the second test pattern TP2. For example, a first resistance (e.g., the resistance A Ra) measured by the test element TEG1 may be the contact resistance between the first test pattern TP1 and the second test pattern TP2.

Therefore, the test element TEG1 may more accurately estimate the contact resistance between the first electrode (see, e.g., E1 of FIG. 2) and the first conductor area (see, e.g., DI1 of FIG. 2). For example, the test element TEG1 may more accurately estimate the contact resistance between the gate electrode layer (see, e.g., GAT of FIG. 2) and the active pattern (see, e.g., ACT of FIG. 2).

The first current I1 may be applied from the first current pad IP1 to the first ground pad GP1. This may be interpreted as that a first current source AM1 is electrically connected between the first current pad IP1 and the first ground pad GP1.

The second current I2 may be applied from the first-second voltage pad VP1-2 to the first-first voltage pad VP1-1. The second current I2 may be applied to measure a first voltage between the first-first voltage pad VP1-1 and the first-second voltage pad VP1-2. This may be interpreted as that a first voltage source VM1 is electrically connected between the first-first voltage pad VP1-1 and the first-second voltage pad VP1-2.

The first resistance may be calculated according to Ohm's law based on the first current I1 and the first voltage. The contact resistance between the first electrode (see, e.g., E1 of FIG. 2) and the first conductor area (see, e.g., DI1 of FIG. 2) may be estimated through the first resistance.

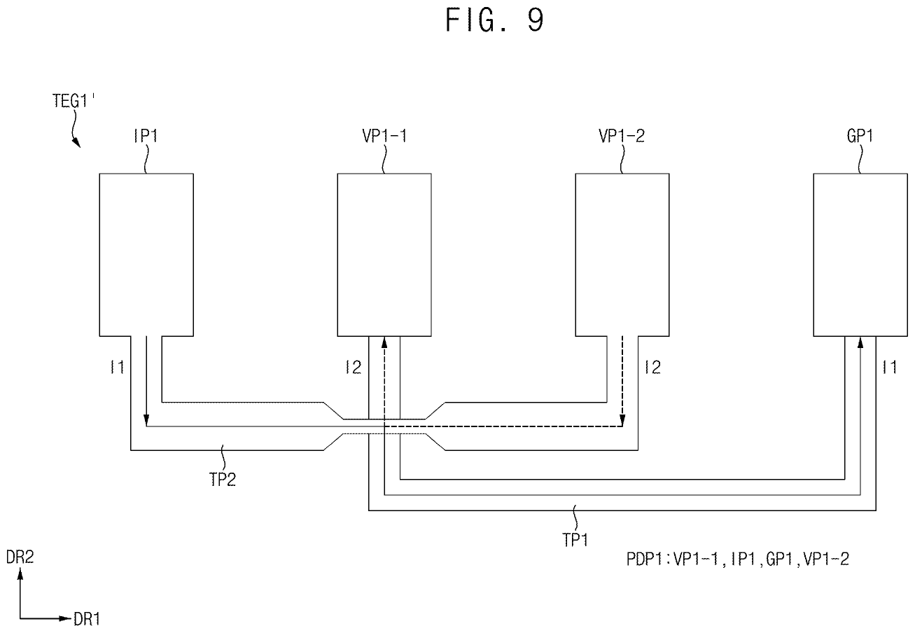

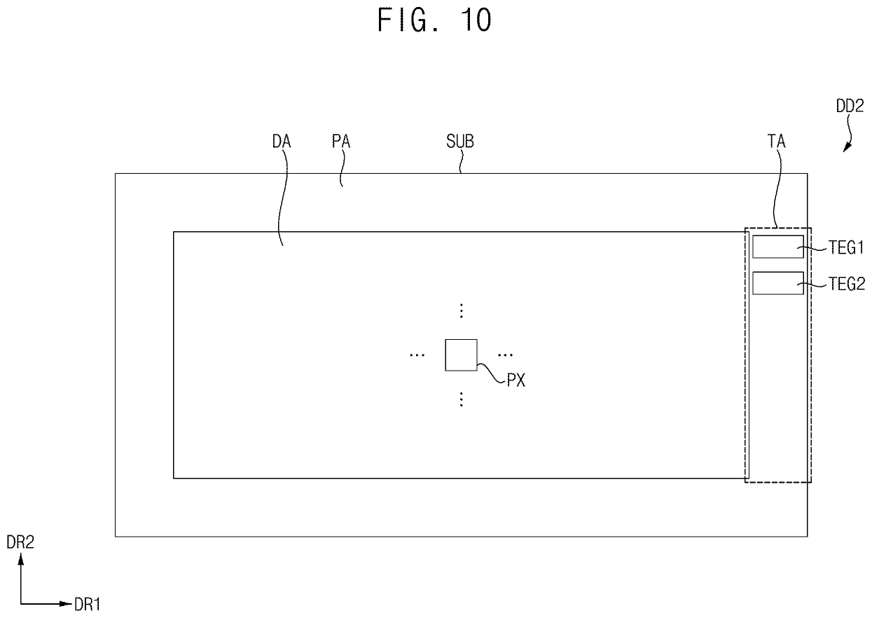

FIG. 9 is a schematic plan view illustrating a test element included in the display device of FIG. 1 according to another embodiment of the disclosure.

Referring to FIGS. 1 and 9, a test element TEG1′ may include a first pad part PDP1, a first test pattern TP1, and a second test pattern TP2.

The test element TEG1′ of FIG. 9 and the test element TEG1 of FIG. 3 may be substantially the same, except for an arrangement order of the first pad part PDP1. Hereinafter, duplicated descriptions of the test element TEG1 of FIG. 3 will be omitted or simplified.

The first pad part PDP1 may be disposed on the substrate SUB in the test area TA. The first pad part PDP1 may include a first-first voltage pad VP1-1, a first-second voltage pad VP1-2, a first current pad IP1, and a first ground pad GP1.

In an embodiment, the first pad part PDP1 may be disposed in the order of the first current pad IP1, the first-first voltage pad VP1-1, the first-second voltage pad VP1-2, and the first ground pad GP1 in the first direction DR1. For example, the first current pad IP1, the first-first voltage pad VP1-1, the first-second voltage pad VP1-2, and the first ground pad GP1 may be disposed side by side in the first direction DR1. Even in case that the first pad part PDP1 are arranged in the above order, at the contact area where the first test pattern TP1 and the second test pattern TP2 contact each other, a direction of the first current I1 flowing into the first ground pad GP1 may be opposite to a direction of the second current I2 flowing into the first-first voltage pad VP1-1.

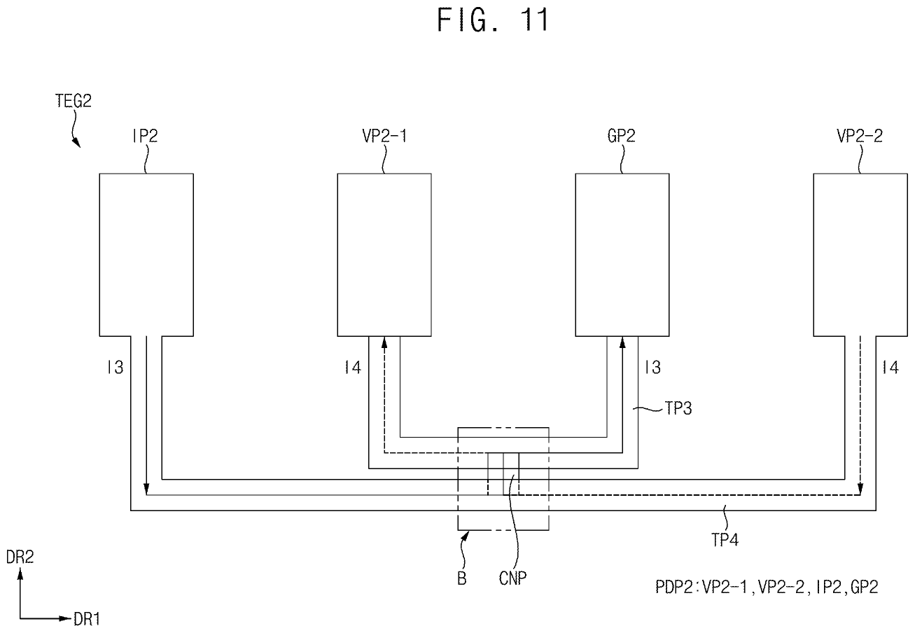

FIG. 10 is a schematic plan view illustrating a display device according to another embodiment of the disclosure.

Referring to FIG. 10, a display device DD2 according to another embodiment of the disclosure may include a substrate SUB, a first test element TEG1, and a second test element TEG2.

The first test element TEG1 of FIG. 10 and the test element TEG1 of FIG. 1 may be substantially the same. For example, the display device DD2 of FIG. 10 and the display device DD of FIGS. 1 and 2 may be substantially the same, except for the second test element TEG2. Hereinafter, duplicated descriptions of the display device DD of FIGS. 1 and 2 will be omitted or simplified.

The substrate SUB may include a display area DA and a peripheral area PA. The peripheral area PA may be disposed adjacent to the display area DA. A test area TA may be disposed inside the peripheral area PA. The test area TA may be disposed adjacent to the display area DA. The first test element TEG1 and the second test element TEG2 may be disposed on the substrate SUB in the test area TA.

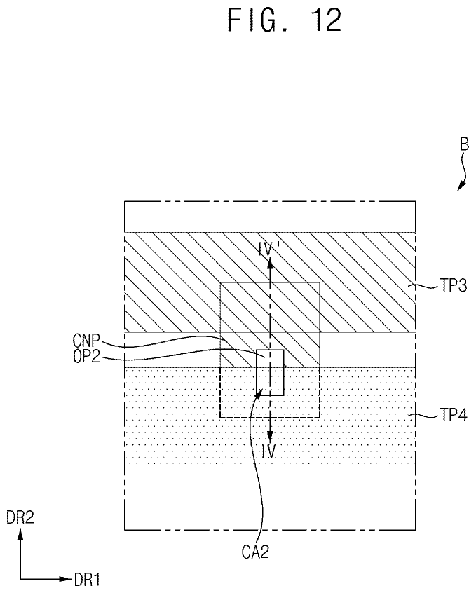

The second test element TEG2 may include multiple pads (see, e.g., a second-first voltage pad VP2-1, a second-second voltage pad VP2-2, a second current pad IP2, and a second ground pad GP2 of FIG. 11) and multiple test patterns (see, e.g., a third test pattern TP3 and a fourth test pattern TP4 of FIG. 11).

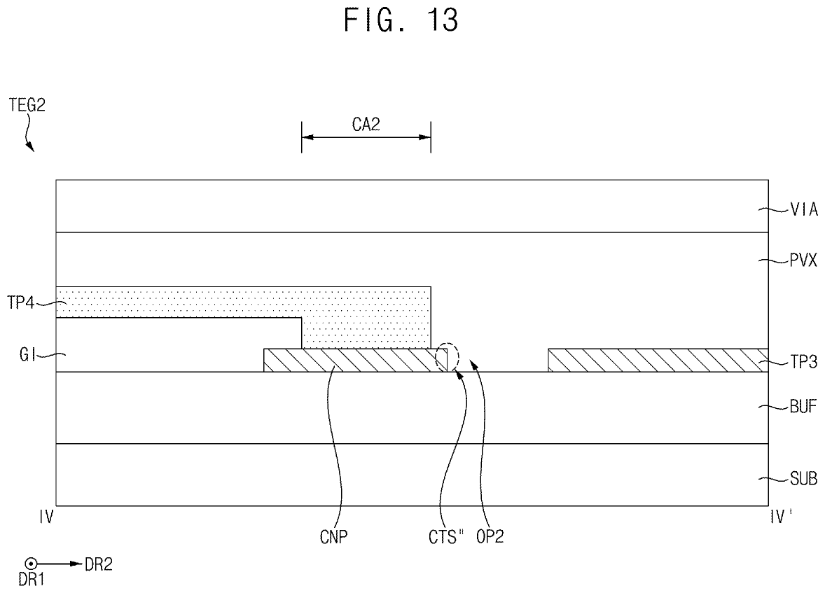

FIG. 11 is a schematic plan view illustrating a second test element included in the display device of FIG. 10. FIG. 12 is a schematic enlarged plan view of area ‘B’ of FIG. 11.

Referring to FIGS. 10, 11, and 12, the display device DD2 according to another embodiment of the disclosure may include the second test element TEG2 disposed on the substrate SUB in the test area TA. The second test element TEG2 may include a second pad part PDP2, a connection pattern CNP, a third test pattern TP3, and a fourth test pattern TP4.

The second pad part PDP2 may be disposed on the substrate SUB in the test area TA. The second pad part PDP2 may include a second-first voltage pad VP2-1, a second-second voltage pad VP2-2, a second current pad IP2, and a second ground pad GP2.

In an embodiment, the second pad part PDP2 may be disposed in the order of the second current pad IP2, the second-first voltage pad VP2-1, the second ground pad GP2, and the second-second voltage pad VP2-2 in the first direction DR1. For example, the second current pad IP2, the second-first voltage pad VP2-1, the second ground pad GP2, and the second-second voltage pad VP2-2 may be disposed side by side in the first direction DR1.

In an embodiment, the second pad part PDP2 of FIG. 11 and the gate electrode layer (see, e.g., GAT of FIG. 2) may be disposed on a same layer. The second pad part PDP2, the first electrode (see, e.g., E1 of FIG. 2), the second electrode (see, e.g., E2 of FIG. 2), and the gate electrode (see, e.g., GE of FIG. 2) may be disposed on a same layer. For example, the second pad part PDP2, the first electrode, the second electrode, and the gate electrode may include a same material, and may be formed by a same process.

The third test pattern TP3 may be disposed on the substrate SUB in the test area TA. The third test pattern TP3 may electrically connect the second-first voltage pad VP2-1 and the second ground pad GP2. The third test pattern TP3 may be electrically connected to each of the second-first voltage pad VP2-1 and the second ground pad GP2 in the second direction DR2 and may extend in the first direction DR1.

In an embodiment, the third test pattern TP3 and the active pattern (see, e.g., ACT of FIG. 2) may be disposed on a same layer. For example, the third test pattern TP3 and the active pattern may include a same material, and may be formed by a same process.

The fourth test pattern TP4 may be disposed on the substrate SUB in the test area TA. The fourth test pattern TP4 may electrically connect the second current pad IP2 and the second-second voltage pad VP2-2. The fourth test pattern TP4 may be electrically connected to each of the second current pad IP2 and the second-second voltage pad VP2-2 in the second direction DR2 and may extend in the first direction DR1. The fourth test pattern TP4 may be spaced apart from the third test pattern TP3 and may contact the connection pattern CNP at a second contact area CA2.

In an embodiment, the fourth test pattern TP4 and the gate electrode layer may be disposed on a same layer. The fourth test pattern TP4, the first electrode, the second electrode, and the gate electrode may be disposed on a same layer. For example, the fourth test pattern TP4, the first electrode, the second electrode, and the gate electrode may include a same material, and may be formed by a same process. In an embodiment, the fourth test pattern TP4 and the second pad part PDP2 may be disposed on a same layer.

The connection pattern CNP may be disposed on the substrate SUB in the test area TA. The connection pattern CNP may electrically connect the third test pattern TP3 and the fourth test pattern TP4. The connection pattern CNP may contact the fourth test pattern TP4 at the second contact area CA2.

In an embodiment, the connection pattern CNP and the active pattern may be disposed on a same layer. For example, the connection pattern CNP and the active pattern may include a same material, and may be formed by a same process. In an embodiment, the connection pattern CNP and the third test pattern TP3 may be disposed on a same layer.

In an embodiment, the fourth test pattern TP4 may be disposed on the third test pattern TP3 and the connection pattern CNP.

To measure a combined resistance (or a combined constant resistance) between the third test pattern TP3 and the fourth test pattern TP4 (see, e.g., a combined resistance Ra′+Rb′+Rc′ of FIG. 15), each of a third current I3 and a fourth current I4 may be applied.

The third current I3 may be applied from the second current pad IP2 to the second ground pad GP2. The third current I3 may flow into the second ground pad GP2 through the second current pad IP2, the fourth test pattern TP4, the connection pattern CNP, and the third test pattern TP3.

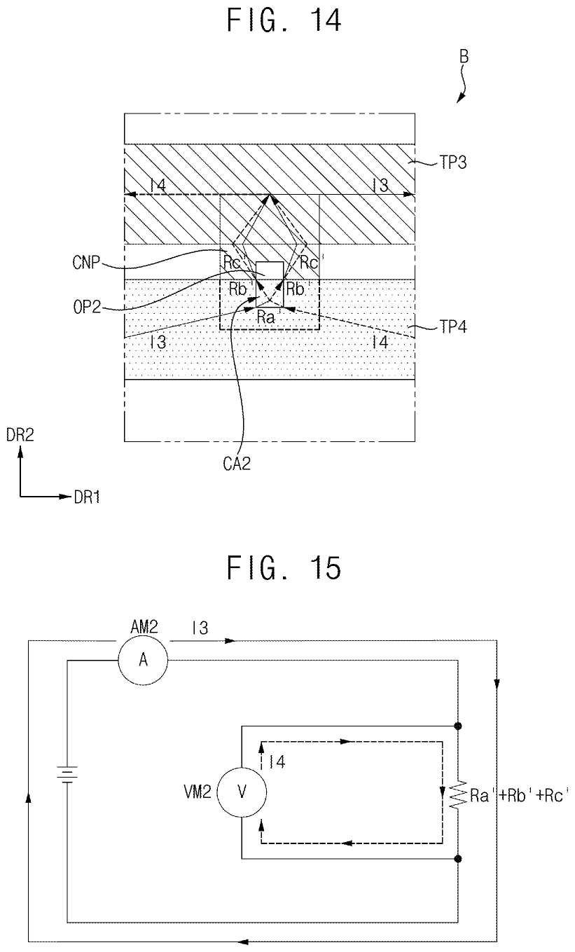

The fourth current I4 may be applied from the second-second voltage pad VP2-2 to the second-first voltage pad VP2-1. The fourth current I4 may flow into the second-first voltage pad VP2-1 through the second-second voltage pad VP2-2, the fourth test pattern TP4, the connection pattern CNP, and the third test pattern TP3. A method of measuring the combined resistance by applying the third current I3 and the fourth current I4 will be described below with reference to FIGS. 14 and 15.

As illustrated in FIG. 12, the fourth test pattern TP4 may be disposed on the third test pattern TP3 and the connection pattern CNP. For example, the fourth test pattern TP4 and the gate electrode layer may be disposed on a same layer. The third test pattern TP3 and the connection pattern CNP and the active pattern may be disposed on a same layer. The fourth test pattern TP4 may contact the connection pattern CNP at the second contact area CA2.

A second opening OP2 penetrating the connection pattern CNP in the thickness direction may be defined in a partial area of the connection pattern CNP. The second opening OP2 may be disposed adjacent to the second contact area CA2 in the second direction DR2. The second opening OP2 may correspond to the opening (see, e.g., OP of FIG. 2).

FIG. 13 is a schematic cross-sectional view taken along line IV-IV′ of FIG. 12. For example, FIG. 13 is a schematic cross-sectional view of the second opening OP2 and the second contact area CA2 taken along the second direction DR2. Hereinafter, duplicated descriptions of the display device DD of FIG. 2 will be omitted or simplified.

Referring to FIGS. 2 and 13, the second test element TEG2 may include the substrate SUB, the buffer layer BUF, the third test pattern TP3, the connection pattern CNP, the gate insulating layer GI, the fourth test pattern TP4, the passivation layer PVX, and the via-insulating layer VIA.

The buffer layer BUF may be disposed on the substrate SUB. The connection pattern CNP and the third test pattern TP3 may be disposed on the buffer layer BUF. The second opening OP2 penetrating the connection pattern CNP in the thickness direction may be defined in a partial area of the connection pattern CNP. The second opening OP2 may be disposed adjacent to the second contact area CA2 in the second direction DR2. The active pattern (see, e.g., ACT of FIG. 2) and each of the connection pattern CNP and the third test pattern TP3 may include a same material, and may be formed by a same process.

The gate insulating layer GI may be disposed on the buffer layer BUF and the connection pattern CNP. The gate insulating layer GI may expose a portion of the connection pattern CNP.

The fourth test pattern TP4 may be disposed on the gate insulating layer GI and the connection pattern CNP. The fourth test pattern TP4 may contact the connection pattern CNP exposed by the gate insulating layer GI. For example, the fourth test pattern TP4 may contact the connection pattern CNP at the second contact area CA2. The fourth test pattern TP4 and the gate electrode layer GAT may include a same material, and may be formed by a same process.

In an embodiment, the second test element TEG2 of FIG. 13 and the contact structure (see, e.g., CTS of FIG. 2) between the first electrode (see, e.g., E1 of FIG. 2) and the first conductor area (see, e.g., DI1 of FIG. 2) may include a substantially identical structure. For example, a contact structure CTS″ between the fourth test pattern TP4 and the connection pattern CNP of FIG. 13 and the contact structure (see, e.g., CTS of FIG. 2) between the first electrode (see, e.g., E1 of FIG. 2) and the first conductor area (see, e.g., DI1 of FIG. 2) may be substantially the same.

The passivation layer PVX may be disposed on the buffer layer BUF, the third test pattern TP3, and the fourth test pattern TP4. For example, the passivation layer PVX may be disposed on the buffer layer BUF, the third test pattern TP3, the connection pattern CNP (e.g., a portion of the connection pattern CNP), and the fourth test pattern TP4. The via-insulating layer VIA may be disposed on the passivation layer PVX. The passivation layer PVX may sufficiently cover each of the third test pattern TP3 and the fourth test pattern TP4 and may have a substantially flat upper surface without creating a step difference on the third test pattern TP3 and the fourth test pattern TP4.

FIG. 14 is a schematic enlarged plan view of area ‘B’ of FIG. 11. For example, FIG. 14 is a schematic plan view illustrating traveling directions of the third current I3 and the fourth current I4. FIG. 15 is a schematic diagram of an equivalent circuit illustrating resistances of FIG. 14.

Referring to FIGS. 11, 14, and 15, the second test element TEG2 may include the second pad part PDP2, the third test pattern TP3, the connection pattern CNP, and the fourth test pattern TP4. The second pad part PDP2 may include the second-first voltage pad VP2-1, the second-second voltage pad VP2-2, the second current pad IP2, and the second ground pad GP2.

In an embodiment, the second current pad IP2, the second-first voltage pad VP2-1, the second ground pad GP2, and the second-second voltage pad VP2-2 may be disposed side by side in the first direction DR1.

The third test pattern TP3 may electrically connect the second-first voltage pad VP2-1 and the second ground pad GP2. The fourth test pattern TP4 may electrically connect the second current pad IP2 and the second-second voltage pad VP2-2. The connection pattern CNP may electrically connect the third test pattern TP3 and the fourth test pattern TP4.

The third current I3 may flow into the second ground pad GP2 through the second current pad IP2, the fourth test pattern TP4, the connection pattern CNP, and the third test pattern TP3. The fourth current I4 may flow into the second-first voltage pad VP2-1 through the second-second voltage pad VP2-2, the fourth test pattern TP4, the connection pattern CNP, and the third test pattern TP3.

Each of the third current I3 and the fourth current I4 may flow from the fourth test pattern TP4 to the connection pattern CNP at the second contact area CA2. Since the second opening OP2 disposed adjacent to the second contact area CA2 in the second direction DR2 is filled with the passivation layer (see, e.g., PVX of FIG. 13) including an insulating material, each of the third current I3 and the fourth current I4 may not flow into the second opening OP2. For example, each of the third current I3 and the fourth current I4 may flow in the connection pattern CNP bypassing the second opening OP2.

Multiple resistances may be generated while each of the third current I3 and the fourth current I4 flows from the fourth test pattern TP4 to the third test pattern TP3. The resistances may include resistance A′ Ra′, resistance B′ Rb′, and resistance C′ Rc′.

For example, the resistance A′ Ra′ may be a contact resistance between the connection pattern CNP and the fourth test pattern TP4 at the second contact area CA2. The resistance A′ Ra′ may be referred to as a first resistance. The resistance B′ Rb′ may be a resistance caused by flow of the third current I3 and the fourth current I4 bypassing the second opening OP2 within the connection pattern CNP. The resistance C′ Rc′ may be an internal resistance of the connection pattern CNP.

In an embodiment, a direction of the third current I3 flowing from the second contact area CA2 to the second ground pad GP2 and a direction of the fourth current I4 flowing from the second contact area CA2 to the second-first voltage pad VP2-1 may be the same. For example, a path of the third current I3 and a path of the fourth current I4 may overlap within the connection pattern CNP including the second contact area CA2 in a plan view.

For example, as illustrated in FIG. 15, the path of the third current I3 and the path of the fourth current I4 may overlap at the resistance A′ Ra′, the resistance B′ Rb′, and the resistance C′ Rc′. In case of using the Kelvin resistance measurement, a resistance value of an area where the third current I3 and the fourth current I4 overlap may be measured. For example, a resistance value obtained by summing the resistance A′ Ra′, the resistance B′ Rb′, and the resistance C′ Rc′ may be measured. For example, resistance (e.g., a combined resistance Ra′+Rb′+Rc′) measured by the second test element TEG2 may be a sum of the resistance A′ Ra′, the resistance B′ Rb′, and the resistance C′ Rc′. The combined resistance Ra′+Rb′+Rc′ may be referred to as a second resistance.

The third current I3 may be applied from the second current pad IP2 to the second ground pad GP2. This may be interpreted as that a second current source AM2 is electrically connected between the second current pad IP2 and the second ground pad GP2.

The fourth current I4 may be applied from the second-second voltage pad VP2-2 to the second-first voltage pad VP2-1. The fourth current I4 may be applied to measure a second voltage between the second-first voltage pad VP2-1 and the second-second voltage pad VP2-2. This may be interpreted as that a second voltage source VM2 is electrically connected between the second-first voltage pad VP2-1 and the second-second voltage pad VP2-2.

The second resistance may be calculated according to Ohm's law based on the third current I3 and the second voltage.

The second test element TEG2 may measure the combined resistance Ra′+Rb′+Rc′, which is the contact resistance (e.g., the resistance A′ Ra′) between the connection pattern CNP and the fourth test pattern TP4 plus a parasitic resistance (e.g., the resistance B′ Rb′ and the resistance C′ Rc′). In contrast, the first test element (see, e.g., the test element TEG1 of FIG. 3) may only measure the contact resistance (see, e.g., the resistance A Ra of FIG. 7) between the first test pattern (see, e.g., TP1 of FIG. 3) and the second test pattern (see, e.g., TP2 of FIG. 3).

In an embodiment, a resistance value (see, e.g., the resistance A Ra of FIG. 3) of the contact resistance between the first test pattern and the second test pattern and a resistance value Ra′ of the contact resistance between the connection pattern CNP and the fourth test pattern TP4 may be the same. A resistance value (see, e.g., the combined resistance Ra′+Rb′+Rc′ of FIG. 15) of the second resistance measured by the second test element TEG2 may be subtracted from the resistance value Ra of the first resistance measured by the first test element TEG1 to calculate a resistance value Rb′+Rc′ of the parasitic resistance between the third test pattern TP3 and the fourth test pattern TP4.

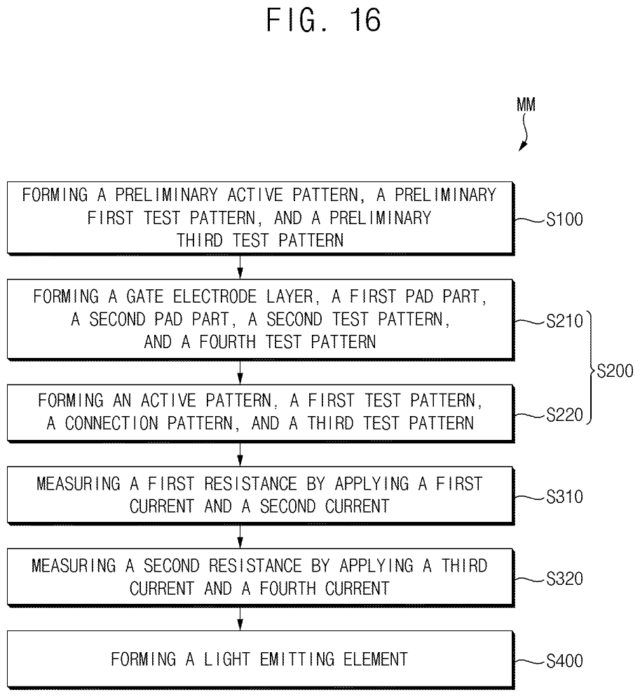

FIG. 16 is a schematic flowchart of a method of manufacturing a display device according to an embodiment of the disclosure.

Referring to FIG. 16, a method MM of manufacturing a display device according to an embodiment of the disclosure may include forming a preliminary active pattern, a preliminary first test pattern, and a preliminary third test pattern (S100), forming a gate electrode layer, a first pad part, a second pad part, a second test pattern, and a fourth test pattern (S210), forming an active pattern, a first test pattern, a connection pattern, and a third test pattern (S220), measuring a first resistance by applying a first current and a second current (S310), measuring a second resistance by applying a third current and a fourth current (S320), and forming a light emitting element (S400).

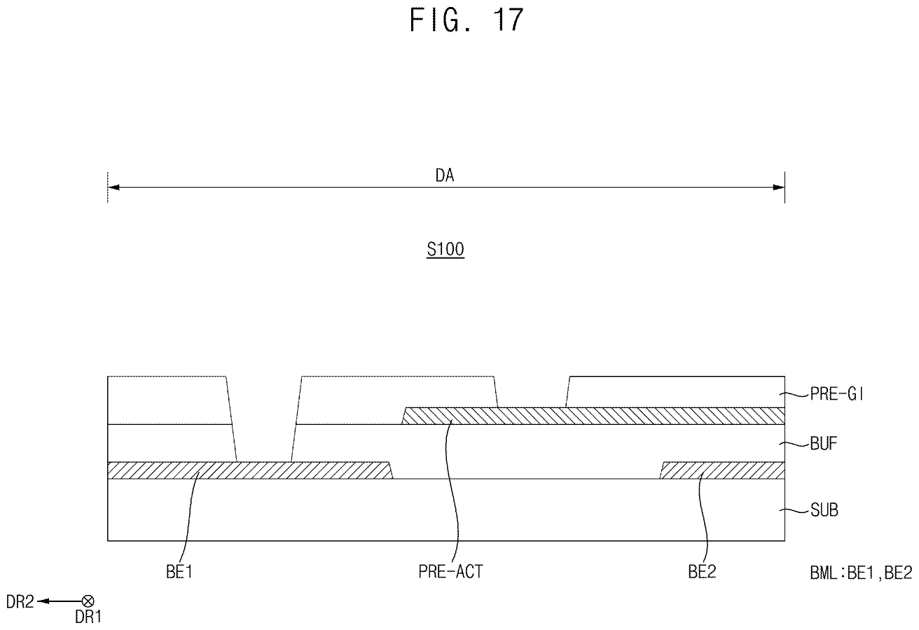

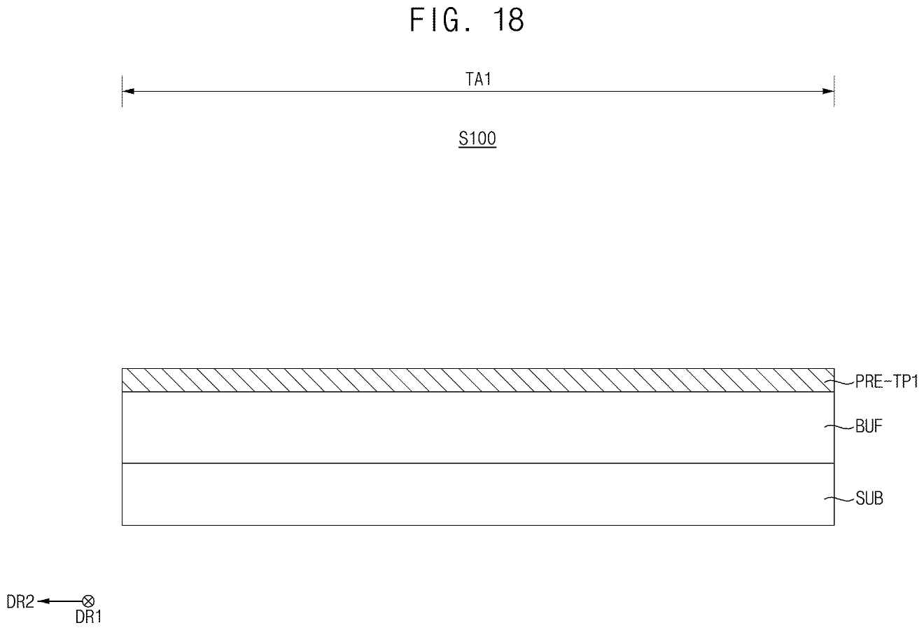

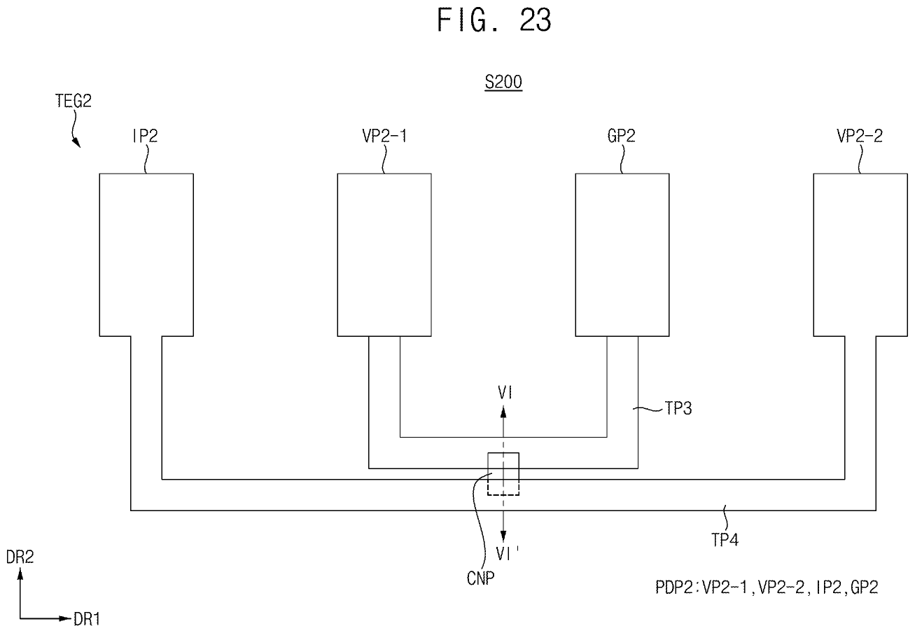

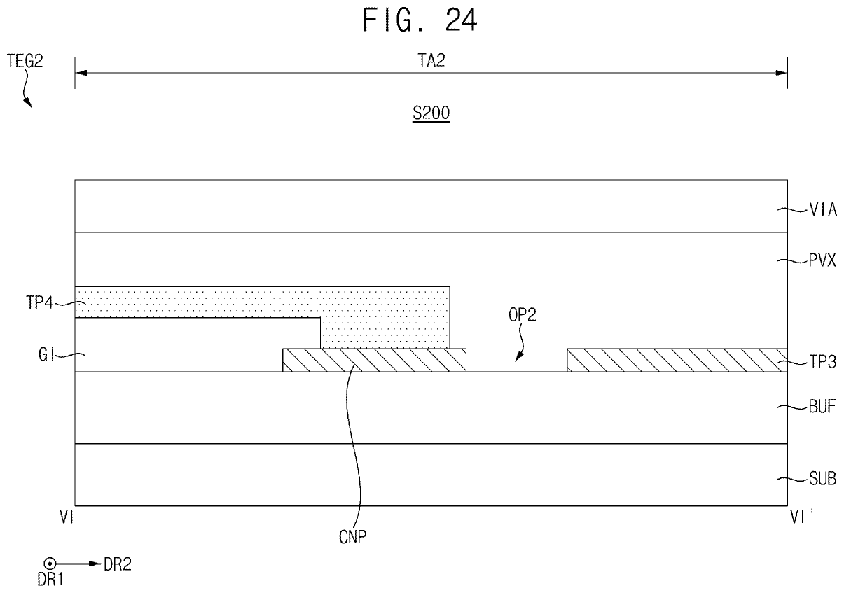

FIGS. 17, 18, 19, 20, 21, 22, 23, 24, 25, 26, and 27 are schematic diagrams illustrating a method of manufacturing the display device of FIG. 16.

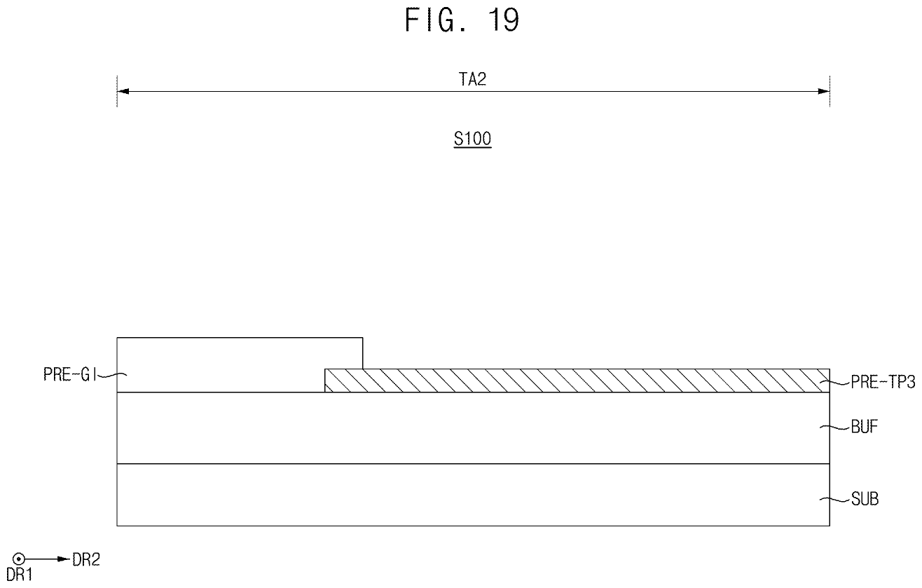

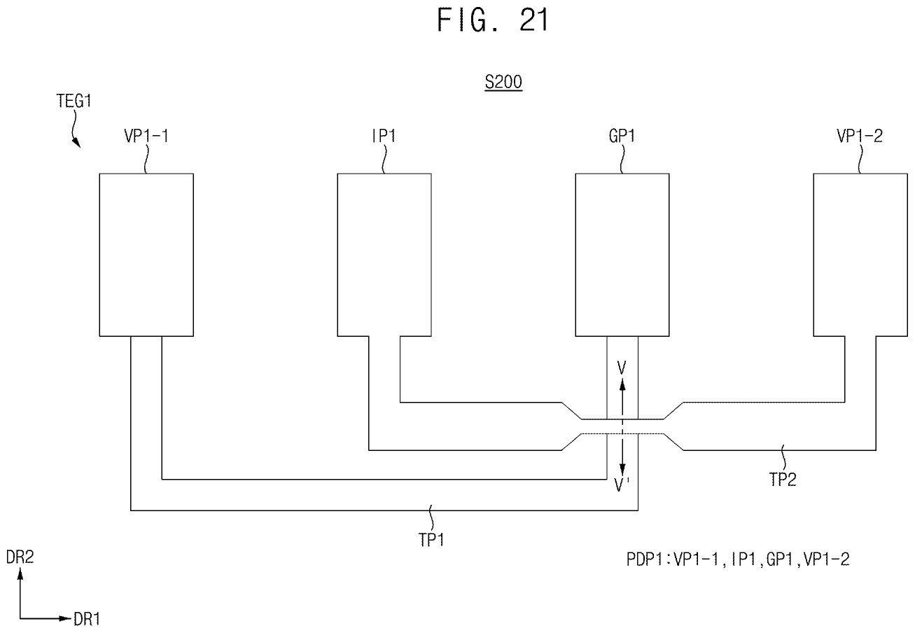

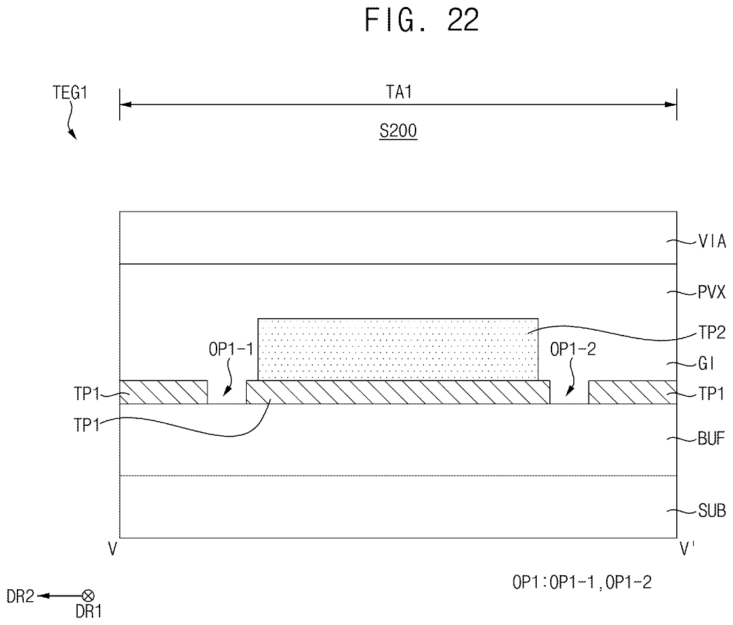

For example, FIGS. 17, 20, and 27 are schematic diagrams illustrating a method of manufacturing a pixel PX included in the display device DD of FIG. 1 and the display device DD2 of FIG. 10. FIGS. 21 and 22 are schematic diagrams illustrating a method of manufacturing a test element TEG1 included in the display device DD of FIG. 1 and a first test element TEG1 included in the display device DD2 of FIG. 10. FIGS. 19, 23, and 24 are schematic diagrams illustrating a method of manufacturing a second test element TEG2 included in the display device DD2 of FIG. 10.

Referring to FIGS. 16, 17, 18, and 19, a preliminary active pattern PRE-ACT, a preliminary first test pattern PRE-TP1, and a preliminary third test pattern PRE-TP3 may be formed (e.g., sequentially formed) on a substrate SUB (S100).

The substrate SUB may include a display area DA and a test area TA. The test area TA may include a first test area TA1 and a second test area TA2. The first test area TA1 may be an area where the first test element TEG1 is formed, and the second test area TA2 may be an area where the second test element TEG2 is formed.

A lower electrode layer BML may be formed on the substrate SUB in the display area DA. The lower electrode layer BML may include a conductive material such as a metal, an alloy, a metal nitride, a conductive metal oxide, a transparent conductive material, the like, or a combination thereof. The lower electrode layer BML may include a first lower electrode BE1 and a second lower electrode BE2. After the conductive material is formed (e.g., entirely formed) on the substrate SUB, the first lower electrode BE1 and the second lower electrode BE2 may be formed by patterning the conductive material using a first mask.

A buffer layer BUF may be formed on the substrate SUB in the display area DA, the first test area TA1, and the second test area TA2. The buffer layer BUF may include an inorganic material such as silicon oxide (SiOₓ), silicon nitride (SiNₓ), silicon oxynitride (SiOₓN_{y}), the like, or a combination thereof.

The preliminary active pattern PRE-ACT may be formed on the buffer layer BUF in the display area DA. The preliminary active pattern PRE-ACT may include an oxide semiconductor, a silicon semiconductor, an organic semiconductor, the like, or a combination thereof. For example, the preliminary active pattern PRE-ACT may be formed by forming (e.g., entirely forming) the oxide semiconductor material on the buffer layer BUF and patterning the oxide semiconductor material using a second mask.

The preliminary first test pattern PRE-TP1 may be formed on the buffer layer BUF in the first test area TA1. The preliminary first test pattern PRE-TP1 and the preliminary active pattern PRE-ACT may include a same material, and may be formed by a same process. For example, the preliminary first test pattern PRE-TP1 may be formed (e.g., entirely formed) on the buffer layer BUF.

The preliminary third test pattern PRE-TP3 may be formed on the buffer layer BUF in the second test area TA2. The preliminary third test pattern PRE-TP3 and the preliminary active pattern PRE-ACT may include a same material, and may be formed by a same process. For example, the preliminary third test pattern PRE-TP3 may be formed by forming (e.g., entirely forming) the oxide semiconductor material on the buffer layer BUF and patterning the oxide semiconductor material using the second mask.

A preliminary gate insulating layer PRE-GI may be formed on the buffer layer BUF in the display area DA and the second test area TA2. The preliminary gate insulating layer PRE-GI may include an inorganic material such as silicon oxide (SiOₓ), silicon nitride (SiNₓ), silicon oxynitride (SiOₓN_{y}), the like, or a combination thereof. The preliminary gate insulating layer PRE-GI may be formed by forming (e.g., entirely forming) the inorganic material on the buffer layer BUF and the preliminary active pattern PRE-ACT and etching the inorganic material using a third mask. Accordingly, the preliminary gate insulating layer PRE-GI may expose a portion of the preliminary active pattern PRE-ACT and a portion of the preliminary third test pattern PRE-TP3. The buffer layer BUF may also be partially etched to expose a portion of the first lower electrode BE1.

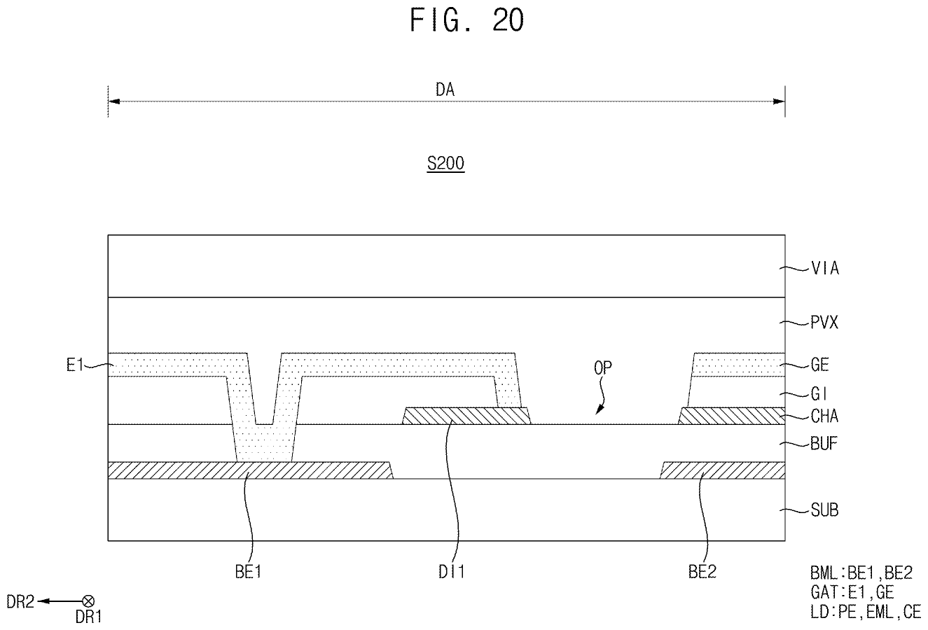

Referring to FIGS. 20, 21, 22, 23, and 24, a gate electrode layer GAT, a first pad part PDP1, a second pad part PDP2, a second test pattern TP2, and a fourth test pattern TP4 may be formed, and an active pattern ACT, a first test pattern TP1, a connection pattern CNP, and a third test pattern TP3 may be formed (S200).

The gate electrode layer GAT may be formed on the lower electrode layer BML, the preliminary active pattern PRE-ACT, and the preliminary gate insulating layer PRE-GI in the display area DA. The gate electrode layer GAT may include a metal, an alloy, a metal nitride, a conductive metal oxide, a transparent conductive material, the like, or a combination thereof.

The gate electrode layer GAT may include a first electrode E1 and a gate electrode GE. The gate electrode layer GAT may be formed by forming (e.g., entirely forming) the conductive material on the lower electrode layer BML, the preliminary active pattern PRE-ACT, and the preliminary gate insulating layer PRE-GI and etching the conductive material using a fourth mask.

In a process of etching the gate electrode layer GAT, a portion of the preliminary gate insulating layer PRE-GI may be etched together to form the gate insulating layer GI. In a process of etching the gate electrode layer GAT and the preliminary gate insulating layer PRE-GI, a portion of the preliminary active pattern PRE-ACT may be etched together to form the active pattern ACT including a first conductor area DI1 and a channel area CHA. An opening OP penetrating the active pattern ACT in the thickness direction may be formed in a partial area of the active pattern ACT.

The first pad part PDP1 may be formed on the substrate SUB in the first test area TA1. The first pad part PDP1 and the gate electrode layer GAT may include a same material, and may be formed by a same process. The first pad part PDP1 may include a first-first voltage pad VP1-1, a first current pad IP1, a first ground pad GP1, and a first-second voltage pad VP1-2.

The second test pattern TP2 may be formed on the preliminary first test pattern PRE-TP1 in the first test area TA1. The second test pattern TP2 and the gate electrode layer GAT may include a same material, and may be formed by a same process. The second test pattern TP2 may be formed by forming (e.g., entirely forming) the conductive material on the preliminary first test pattern PRE-TP1 and etching the conductive material using the fourth mask.

In a process of etching the second test pattern TP2, a portion of the preliminary first test pattern PRE-TP1 may be etched together to form the first test pattern TP1. For example, first openings OP1 penetrating the first test pattern TP1 in the thickness direction may be formed in a partial area of the first test pattern TP1.

In an embodiment, in a plan view, the first pad part PDP1 may be arranged in the order of the first-second voltage pad VP1-1, the first current pad IP1, the first ground pad GP1, and the first-second voltage pad VP1-2 in the first direction DR1.

In another embodiment, in a plan view, the first pad part PDP1 may be arranged in the order of the first current pad IP1, the first-first voltage pad VP1-1, the first-second voltage pad VP1-2, and the first ground pad GP1 in the first direction DR1.

In a plan view, the first test pattern TP1 may electrically connect the first-first voltage pad VP1-1 and the first ground pad GP1. The second test pattern TP2 may electrically connect the first current pad IP1 and the first-second voltage pad VP1-2.

The second pad part PDP2 may be formed on the substrate SUB in the second test area TA2. The second pad part PDP2 and the gate electrode layer GAT may include a same material, and may be formed by a same process. The second pad part PDP2 may include a second current pad IP2, a second-first voltage pad VP2-1, a second ground pad GP2, and a second-second voltage pad VP2-2.

The fourth test pattern TP4 may be formed on the preliminary third test pattern PRE-TP3 and the preliminary gate insulating layer PRE-GI in the second test area TA2. The fourth test pattern TP4 and the gate electrode layer GAT may include a same material, and may be formed through a same process. The fourth test pattern TP4 may be formed by forming (e.g., entirely forming) the conductive material on the preliminary third test pattern PRE-TP3 and the preliminary gate insulating layer PRE-GI and etching the conductive material using the fourth mask.

In a process of etching the fourth test pattern TP4, a portion of the preliminary third test pattern PRE-TP3 may be etched together to form the connection pattern CNP and the third test pattern TP3. For example, a second opening OP2 penetrating the connection pattern CNP in the thickness direction may be formed in a partial area of the connection pattern CNP.

In an embodiment, in a plan view, the second pad part PDP2 may be arranged in the order of the second current pad IP2, the second-first voltage pad VP2-1, the second ground pad GP2, and the second-second voltage pad VP2-2 in the first direction DR1.

In a plan view, the third test pattern TP3 may electrically connect the second-first voltage pad VP2-1 and the second ground pad GP2. The fourth test pattern TP4 may electrically connect the second current pad IP2 and the second-second voltage pad VP2-2. The connection pattern CNP may electrically connect the third test pattern TP3 and the fourth test pattern TP4.

A passivation layer PVX may be formed on the buffer layer BUF and the gate electrode layer GAT in the display area DA. The passivation layer PVX may cover the first electrode E1 and the gate electrode GE. The passivation layer PVX may cover the active pattern ACT not covered by the gate insulating layer GI. The passivation layer PVX may include an inorganic material such as silicon oxide (SiOₓ), silicon nitride (SiNₓ), silicon oxynitride (SiOₓN_{y}), the like, or a combination thereof.

The passivation layer PVX may be formed on the buffer layer BUF, the first test pattern TP1, and the second test pattern TP2 in the first test area TA1. The passivation layer PVX may cover the first test pattern TP1 and the second test pattern TP2.

The passivation layer PVX may be formed on the buffer layer BUF, the third test pattern TP3, and the fourth test pattern TP4 in the second test area TA2. The passivation layer PVX may cover the third test pattern TP3, the connection pattern CNP, and the fourth test pattern TP4.

A via-insulating layer VIA may be formed on the passivation layer PVX in the display area DA, the first test area TA1, and the second test area TA2. The via-insulating layer VIA may include an organic material such as photoresist, a polyacryl-based resin, a polyimide-based resin, a polyamide-based resin, a siloxane-based resin, an epoxy-based resin, the like, or a combination thereof.

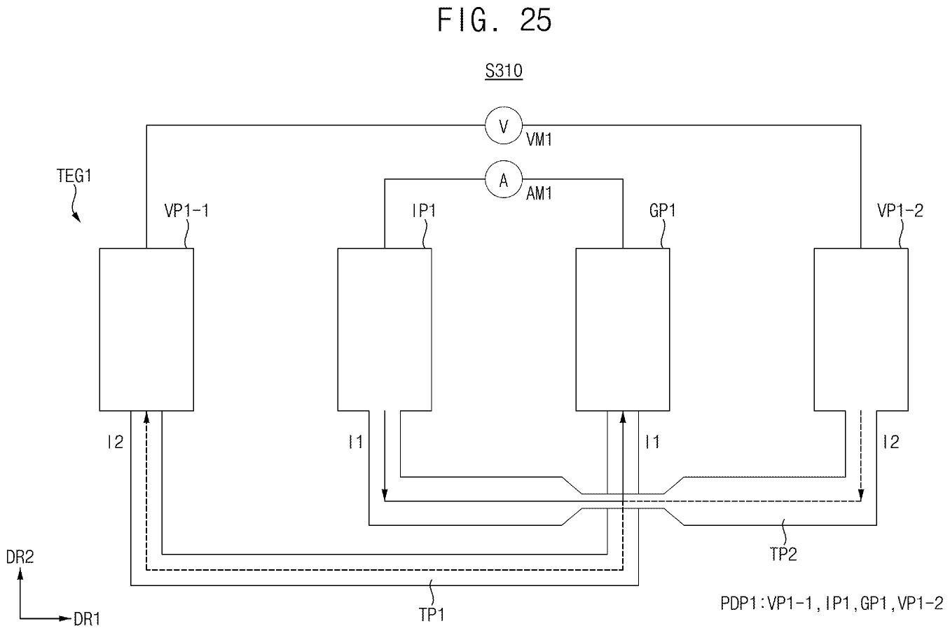

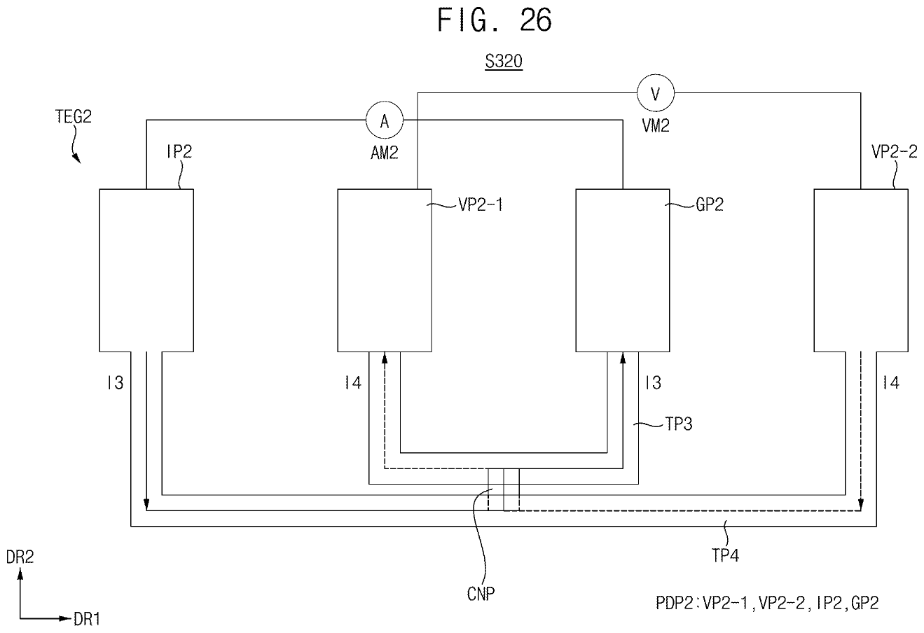

Referring to FIGS. 25 and 26, a first resistance may be measured by applying a first current I1 and a second current I2 (S310). A second resistance may be measured by applying a third current I3 and a fourth current I4 (S320). The measuring of the first resistance (S310) and the measuring of the second resistance (S320) may be performed simultaneously.

The first current I1 may be applied from the first current pad IP1 to the first ground pad GP1. This may be interpreted as that a first current source AM1 is electrically connected between the first current pad IP1 and the first ground pad GP1. The first current I1 may flow into the first ground pad GP1 through the first current pad IP1, the second test pattern TP2, and the first test pattern TP1.

The second current I2 may be applied from the first-second voltage pad VP1-2 to the first-first voltage pad VP1-1. The second current I2 may be applied to measure a first voltage between the first-first voltage pad VP1-1 and the first-second voltage pad VP1-2. This may be interpreted as that a first voltage source VM1 is electrically connected between the first-first voltage pad VP1-1 and the first-second voltage pad VP1-2. The second current I2 may flow into the first-first voltage pad VP1-1 through the first-second voltage pad VP1-2, the second test pattern TP2, and the first test pattern TP1.

The first resistance may be calculated according to Ohm's law based on the first current I1 and the first voltage. The first resistance may correspond to the resistance A Ra of FIG. 7.

The third current I3 may be applied from the second current pad IP2 to the second ground pad GP2. This may be interpreted as that a second current source AM2 is electrically connected between the second current pad IP2 and the second ground pad GP2. The third current I3 may flow into the second ground pad GP2 through the second current pad IP2, the fourth test pattern TP4, the connection pattern CNP, and the third test pattern TP3.

The fourth current I4 may be applied from the second-second voltage pad VP2-2 to the second-first voltage pad VP2-1. The fourth current I4 may be applied to measure a second voltage between the second-first voltage pad VP2-1 and the second-second voltage pad VP2-2. This may be interpreted as that a second voltage source VM2 is electrically connected between the second-first voltage pad VP2-1 and the second-second voltage pad VP2-2. The fourth current I4 may flow into the second-first voltage pad VP2-1 through the second-second voltage pad VP2-2, the fourth test pattern TP4, the connection pattern CNP, and the third test pattern TP3.

The second resistance may be calculated according to Ohm's law based on the third current I3 and the second voltage. The second resistance may correspond to the combined resistance Ra′+Rb′+Rc′ of FIG. 15.

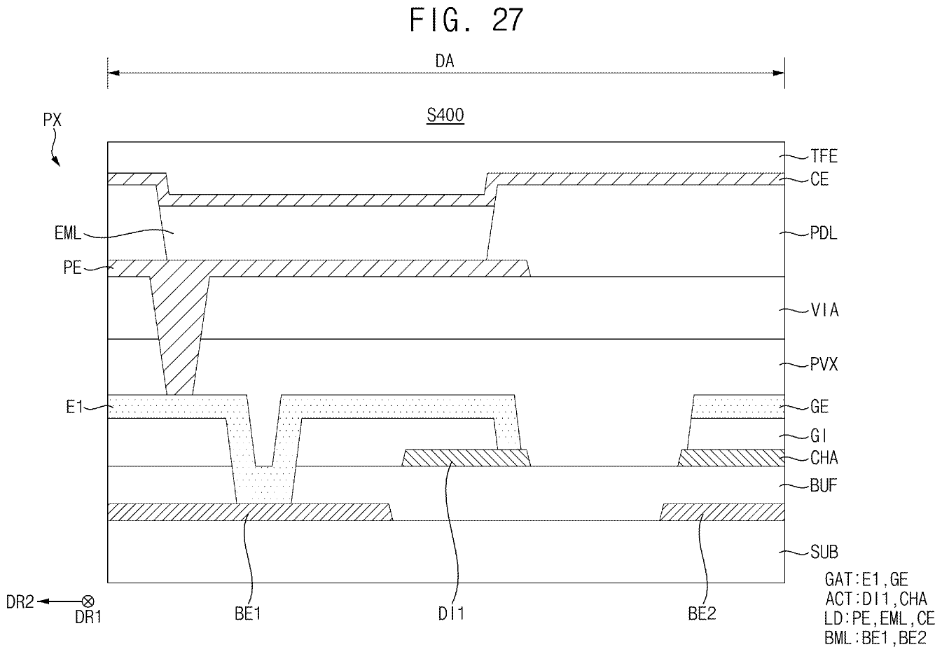

Referring to FIG. 27, a light emitting element LD may be formed on the via-insulating layer VIA (S400).

The via-insulating layer VIA and the passivation layer PVX may be etched using a fifth mask in the display area DA. Accordingly, a contact hole exposing the first electrode E1 may be formed through the via-insulating layer VIA and the passivation layer PVX.

A pixel electrode PE may be formed on the via-insulating layer VIA. The pixel electrode PE may be electrically connected to the first electrode E1 by filling the contact hole. The pixel electrode PE may include a conductive material such as a metal, an alloy, a metal nitride, a conductive metal oxide, a transparent conductive material, the like, or a combination thereof. The pixel electrode PE may be formed by forming (e.g., entirely forming) the conductive material on the via-insulating layer VIA and patterning the conductive material using a sixth mask.

A pixel defining layer PDL may be formed on the via-insulating layer VIA. The pixel defining layer PDL may cover an edge of the pixel electrode PE and may expose a portion of an upper surface of the pixel electrode PE. The pixel defining layer PDL may include an organic material and/or an inorganic material. In an embodiment, the pixel defining layer PDL may include an organic material. The pixel defining layer PDL may be formed by forming (e.g., entirely forming) the organic material on the via-insulating layer VIA and the pixel electrode PE and patterning the organic material using a seventh mask.

A light emitting layer EML may be formed on the pixel electrode PE. The light emitting layer EML may include an organic material that emits light of a color (e.g., a predetermined or selectable color). For example, the light emitting layer EML may be formed on the pixel electrode PE by using a fine metal mask (FMM). For example, the light emitting layer EML may be formed on the pixel electrode PE by an inkjet printing method without using a mask. For example, a mask may not be used in case that forming the light emitting layer EML.

A common electrode CE may be formed on the pixel defining layer PDL and the light emitting layer EML. The common electrode CE may be formed (e.g., entirely formed) to cover each of the pixel defining layer PDL and the light emitting layer EML. A mask may not be used during forming the common electrode CE. The common electrode CE may include a metal, an alloy, a metal nitride, a conductive metal oxide, a transparent conductive material, the like, or a combination thereof.

An encapsulation layer TFE may be formed on the common electrode CE. The encapsulation layer TFE may include at least one inorganic encapsulation layer and at least one organic encapsulation layer.

The disclosure may be applied to various display devices. For example, the disclosure may be applicable to various display devices such as display devices for vehicles, ships, or aircraft, portable communication devices, display devices for exhibition or information transmission, medical display devices, and the like.

The above description is an example of technical features of the disclosure, and those skilled in the art to which the disclosure pertains will be able to make various modifications and variations. Therefore, the embodiments of the disclosure described above may be implemented separately or in combination with each other.

Therefore, the embodiments disclosed in the disclosure are not intended to limit the technical spirit of the disclosure, but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. A display device comprising:
a display area and a test area disposed adjacent to the display area; and
a first test element disposed on a substrate in the test area, wherein the first test element comprises:
a first pad part including a first-first voltage pad, a first-second voltage pad, a first current pad, and a first ground pad;
a first test pattern electrically connecting the first-first voltage pad and the first ground pad; and
a second test pattern contacting the first test pattern and electrically connecting the first current pad and the first-second voltage pad, and
in an area where the first test pattern and the second test pattern contact each other, a direction of a first current that flows into the first ground pad and a direction of a second current that flows into the first-first voltage pad are opposite to each other.

2. The display device of claim 1, wherein
the first current flows into the first ground pad through the first current pad, the second test pattern, and the first test pattern, and
the second current flows into the first-first voltage pad through the first-second voltage pad, the second test pattern, and the first test pattern.

3. The display device of claim 1, wherein the first-first voltage pad, the first current pad, the first ground pad, and the first-second voltage pad are arranged side by side in a first direction.

4. The display device of claim 1, wherein the first current pad, the first-first voltage pad, the first-second voltage pad, and the first ground pad are arranged side by side in a first direction.

5. The display device of claim 1, further comprising:
an active pattern disposed on the substrate in the display area; and
a gate electrode layer disposed on the active pattern, wherein the first test pattern and the active pattern are disposed on a same layer, and
the gate electrode layer and each of the second test pattern and the first pad part are disposed on a same layer.

6. The display device of claim 5, wherein
the first test pattern and the active pattern include a same material, and
the gate electrode layer and each of the second test pattern and the first pad part include a same material.

7. The display device of claim 1, further comprising:
a second test element disposed on the substrate in the test area, wherein the second test element includes:
a second pad part including a second-first voltage pad, a second-second voltage pad, a second current pad, and a second ground pad;
a third test pattern electrically connecting the second-first voltage pad and the second ground pad;
a fourth test pattern electrically connecting the second current pad and the second-second voltage pad; and
a connection pattern electrically connecting the third test pattern and the fourth test pattern, and
in an area where the connection pattern and the fourth test pattern contact each other, a direction of a third current that flows into the second ground pad and a direction of fourth current that flows into the second-first voltage pad are same.

8. The display device of claim 7, wherein
the third current flows into the second ground pad through the second current pad, the fourth test pattern, the connection pattern, and the third test pattern, and
the fourth current flows into the second-first voltage pad through the second-second voltage pad, the fourth test pattern, the connection pattern, and the third test pattern.

9. The display device of claim 7, wherein the second current pad, the second-first voltage pad, the second ground pad, and the second-second voltage pad are arranged side by side in a first direction.

10. The display device of claim 7, further comprising:
an active pattern disposed on the substrate in the display area; and a gate electrode layer disposed on the active pattern, wherein
the active pattern and each of the third test pattern and the connection pattern are disposed on a same layer, and
the gate electrode layer and each of the fourth test pattern and the second pad part are disposed on a same layer.

11. The display device of claim 10, wherein
the active pattern and each of the third test pattern and the connection pattern include a same material, and
the gate electrode layer and each of the fourth test pattern and the second pad part include a same material.

12. A method of manufacturing a display device, the method comprising:
providing a substrate including a display area and a test area disposed adjacent to the display area;
forming a first pad part including a first-first voltage pad, a first-second voltage pad, a first current pad, and a first ground pad on the substrate in the test area;
forming a first test pattern electrically connecting the first-first voltage pad and the first ground pad on the substrate in the test area; and
forming a second test pattern contacting the first test pattern and electrically connecting the first current pad and the first-second voltage pad on the substrate in the test area,
wherein in an area where the first test pattern and the second test pattern contact each other, a direction of a first current that flows into the first ground pad and a direction of a second current that flows into the first-first voltage pad are opposite to each other.

13. The method of claim 12, further comprising:
applying the first current from the first current pad to the first ground pad;
applying the second current from the first-second voltage pad to the first-first voltage pad;
measuring a first voltage between the first-first voltage pad and the first-second voltage pad; and
calculating a first resistance of the area where the first test pattern and the second test pattern contact each other by using the first current and the first voltage.

14. The method of claim 12, wherein the first-first voltage pad, the first current pad, the first ground pad, and the first-second voltage pad are formed side by side in a first direction.

15. The method of claim 12, wherein the first current pad, the first-second voltage pad, the first-second voltage pad, and the first ground pad are formed side by side in a first direction.

16. The method of claim 12, further comprising:
forming an active pattern on the substrate in the display area; and
forming a gate electrode layer on the active pattern, wherein the first test pattern and the active pattern are formed simultaneously, and
the gate electrode layer, the second test pattern, and the first pad part are formed simultaneously.

17. The method of claim 13, further comprising:
forming a second pad part including a second-first voltage pad, a second-second voltage pad, a second current pad, and a second ground pad on the substrate in the test area;
forming a third test pattern electrically connecting the second-first voltage pad and the second ground pad on the substrate in the test area;
forming a fourth test pattern electrically connecting the second current pad and the second-second voltage pad on the substrate in the test area; and
forming a connection pattern electrically connecting the third test pattern and the fourth test pattern on the substrate in the test area,
wherein in an area where the connection pattern and the fourth test pattern contact each other, a direction of a third current that flows into the second ground pad and a direction of a fourth current that flows into the second-first voltage pad are same.

18. The method of claim 17, further comprising:
applying the third current from the second current pad to the second ground pad;
applying the fourth current from the second-second voltage pad to the second-first voltage pad;
measuring a second voltage between the second-first voltage pad and the second-second voltage pad; and
calculating a second resistance by using the third current and the second voltage.

19. The method of claim 18, wherein
the second resistance includes a resistance of the area where the connection pattern and the fourth test pattern contact each other, and
the second resistance is greater than the first resistance.

20. The method of claim 18, wherein the first resistance and a resistance value of a resistance of the area where the connection pattern and the fourth test pattern contact each other are equal.
